(19) United States
(12) Patent Application Publication
(10) Pub. No.: US 2022/0030681 A1
(43) Pub. Date: Jan. 27, 2022

(54) EDGE-LIT BIO-FRIENDLY LIGHTING SYSTEM

(71) Applicant: Bambu Vault LLC, Lowell, MA (US)

(72) Inventors: Ying LI, Westmont, IL (US); Satish AGRAWAL, Sudbury, MA (US); Michael G. HORNER, West Roxbury, MA (US); Andrew TURK, Woodbridge, IL (US); Nathaniel KABAT, Burr Ridge, IL (US)

(21) Appl. No.: 17/292,421

(22) PCT Filed: Nov. 10, 2019
(86) PCT No.: PCT/US19/60666

§ 371 Date: May 7, 2021

Related U.S. Application Data
(60) Provisional application No. 62/758,444, filed on Nov. 9, 2018.
(60) Provisional application No. 62/850,477, filed on May 20, 2019.
(60) Provisional application No. 62/850,341, filed on May 20, 2019.
(60) Provisional application No. 62/850,360, filed on May 20, 2019.
(60) Provisional application No. 62/850,487, filed on May 20, 2019.
(60) Provisional application No. 62/850,353, filed on May 20, 2019.
(60) Provisional application No. 62/850,483, filed on May 20, 2019.
(60) Provisional application No. 62/850,346, filed on May 20, 2019.
(60) Provisional application No. 62/850,480, filed on May 20, 2019.
(60) Provisional application No. 62/850,350, filed on May 20, 2019.
(60) Provisional application No. 62/851,332, filed on May 22, 2019.

(51) Int. Cl. H05B 45/20; A01G 7/04; F21V 14/00; F21V 9/30; H05B 47/16

(52) U.S. Cl. CPC H05B 45/20; A01G 7/045; H05B 47/16; F21V 9/30; F21V 14/006

(57) ABSTRACT

A lighting device that provides visible illumination with enhanced emission in the range 460-520 nm with a M/P ratio of XI, where XI is at least 0.7, a correlated color temperature of 4000-14000 K, and an average color rendering index of at least 70.

### CROSS REFERENCE TO RELATED APPLICATIONS

The present application claims the benefit of priority under 35 U.S.C. § 119(e) to U.S. Provisional Application No. 62/758,444, filed on Nov. 9, 2018, and 62/850,341, 62/850,477, 62/850,480, 62/850,483, 62/850,346, 62/850,350, 62/850,360, 62/850,487, 62/850,353, and 62/851,332, filed on May 20, 2019, all which are incorporated by reference herein by their entireties.

### TECHNICAL FIELD

The present disclosure relates to devices and systems which are configured to provide visible lighting with enhanced and/or decreased melanopic flux and/or enhanced and/or decreased melanopic lux to photopic lux ratio.

### BACKGROUND

Research relating to circadian rhythm, e.g., processes regulating the sleep-wake cycle, suggests that the spectral composition of the light received by humans (and other living beings) plays a significant role in circadian entrainment. Given the amount of time humans spend working under artificial lights, ailments attributed to disruption of circadian rhythm have become increasingly common. Thus, efforts are underway to design indoor lighting systems that can generate light having a spectrum tailored to induce desired melanopic response.

For example, lighting systems can take advantage of this melanopic response to provide light with high melanopic content to stimulate alertness. In contrast, lighting in which the melanopic flux has been significantly reduced can be used to encourage restfulness and sleep. While much literature refers to the inhibitory effect of blue light, especially as regards the use of LED lighting, it is important to recognize that the important regulatory response is associated with incident light in the wavelength range from 460 nm to 520 nm and peaks at wavelength range from 480 nm to 490 nm, and not just “blue light”.

The production of light enriched in melanopic flux has been limited in common white light systems by the use of cerium-doped YAG phosphors to convert blue LED source light to longer wavelengths. As a result, many lamps today exhibit a minimum in the spectral energy distribution near 480 nm. Attempts have been made to fill the spectral gap by designing emitters to produce light in the 480-500 nm band. This “semiconductor” approach will be expensive due to the extensive R&D required and the low manufacturing volumes due to the specialized nature of this application. Likewise, the use of blue-emitting chips whose peak emission is in the range of 450-470 nm in conventional white light systems introduces undesirable melanopic flux when such systems are a primary source of illumination prior to sleep. There is a need for lighting systems that can control and optimize the melanopic flux of lux for lighting environments.

### BRIEF DESCRIPTION

Previous publications have described the use of energy conversion technology to produce useful, sustainable white light emission from blue emission sources (e.g., U.S. Pat. No. 8,415,642, incorporated herein by reference). This approach to the production of white light with high CRI has proven successful over a broad range of color temperatures. Careful choice of energy conversion components can be used to broadly tune the emission spectrum to achieve advantageous effects, including providing light in the melanopic range.

In some embodiments, a lighting device that provides high melanopic flux with good CRI and luminous efficacy is described. A light source is disposed inside a frame in communication with at least a portion of an edge of a light guide panel positioned in the frame. The light guide panel directs the light emitted by the light source when powered to a viewing hemisphere. An energy conversion component is disposed between the light source and the corresponding portion of the edge of the light guide panel. The energy conversion component converts at least a portion of light incident on the energy conversion component from the light source to a light having a longer wavelength.

In another embodiment, a light source is disposed in a frame in communication with at least a portion of an edge of a light guide panel positioned in the frame. The light guide panel which directs the light emitted by the light source when powered to a viewing hemisphere. An energy conversion component is disposed over a surface of the light guide panel facing the viewing hemisphere. The energy conversion component converts at least a portion of light incident on the energy conversion component from the light guide panel to a light having a longer wavelength.

In some embodiments, the light source is disposed inside a U-shaped bracket or channel, which is disposed inside the frame. In such embodiments, the relative position of the light source and the other optical components including the light guide panel, the energy conversion film, the diffuser, the reflector, etc. as shown in FIG. 1B. The energy conversion film, in such embodiments, can be positioned between the light source and the corresponding edge of the light guide panel or over the front face of light guide panel.

In yet another embodiment, a first light source is disposed inside a frame in communication with a first portion of an edge of a light guide panel positioned in the frame, and a second light source is disposed inside a second portion of the edge of the frame in communication with a second portion of the edge of the light guide panel. In some embodiments, the first and second light sources have independent electrical control system. In some embodiments, the first and second light sources are coupled to a same electrical control system. The light guide panel which directs the light emitted by the first and second light sources to a viewing hemisphere. A first energy conversion component is disposed between the first light source and the first portion of the edge of the light guide panel, and a second energy conversion component is disposed between the second light source and the second portion of the edge of the light guide panel. The first and second energy conversion components are configured to convert at least a portion of light incident on the respective energy conversion component from the corresponding light source to a light having a longer wavelength and the light converted by the first energy conversion component has a different spectral composition than that of the light converted by the second energy conversion component.

In some embodiments, the light source(s) include an LED emitter near the high energy region of the melanopic spectral sensitivity or response function and energy conversion components are configured to provide significant light in the region of 480-500 nm in order to obtain high melanopic flux. In some embodiments, a lighting device according to the present disclosure provides high melanopic flux by configuring the light source(s) and energy conversion components to achieve a melanopic lux to photopic lux (M/P ratio) that is at least 0.7, 0.8, 0.9, 1.0, 1.1, or 1.2. An M/P ratio of about 0.9 to about 1.3 (e.g., 1.0-1.2) may be preferred in some embodiments, since this assures high melanopic efficacy. In some embodiments, the remainder of the spectral energy is distributed so as to obtain a CRI of, for example, at least 75 and luminous efficacy of at least 70 lm/watt.

In further embodiments, a lighting device that provides a low melanopic flux with a good CRI and luminous efficacy is described. A blue component to white light is provided in some embodiments by an LED emitter with a peak emission wavelength in the range 400-460 nm. An M/P ratio of about 0.09 to about 0.40 (e.g., 0.10-0.35) may be achieved in some embodiments when low melanopic flux is desired. In some embodiments, a lighting device according to the present disclosure has an M/P ratio that is no greater than 0.50, 0.40, 0.30, 0.20, or 0.10. In some embodiments, a white light spectrum is produced with high efficacy by converting a significant amount of blue light to longer wavelengths so as to obtain, for example, a CRI of at least 70 and a luminous efficacy of at least 60 lm/watt.

### BRIEF DESCRIPTION OF DRAWINGS

In the present disclosure, reference is made to the accompanying drawings, which form a part hereof. In the drawings, similar symbols typically identify similar components, unless context dictates otherwise. The illustrative embodiments described in the detailed description, drawings, and claims are not meant to be limiting. Some embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

FIG. 1 illustrates an example structure of an edge-lit luminaire, in accordance with an embodiment of the present disclosure.

FIG. 2 illustrates a side-channel disposed inside the frame of an edge-lit luminaire, in accordance with an embodiment of the present disclosure.

FIG. 3 illustrates another example structure of an edge-lit luminaire, in accordance with an embodiment of the present disclosure.

FIGS. 4A-4C illustrate further examples of edge-lit lighting devices, in accordance with an embodiment of the present disclosure.

FIGS. 4D and 4E illustrate examples of lighting devices with different shapes, in accordance with some embodiments of the present disclosure.

FIG. 5A illustrates an example structure of a back-lit luminaire, in accordance with an embodiment of the present disclosure.

FIG. 5B illustrates an example of a back-lit luminaire that can produce light with several different output spectra, in accordance with an embodiment of the present disclosure.

FIGS. 5C-5F shows various examples of positioning of LED strips in back-lit luminaires, in accordance with an embodiment of the present disclosure.

FIG. 6 depicts a graph showing the light intensity over time emitted by a lighting device, in accordance with an embodiment of the present disclosure.

FIG. 7A illustrates an example of an apparatus used for changing an energy conversion component of an edge-lit lighting device, in accordance with an embodiment of the present disclosure.

FIG. 7B illustrates another example of an apparatus used for changing an energy conversion component of an edge-lit lighting device, in accordance with an embodiment of the present disclosure.

FIG. 8A illustrates an example of an apparatus used for changing an energy conversion component of a back-lit lighting device, in accordance with an embodiment of the present disclosure.

FIG. 8B illustrates another example of an apparatus used for changing an energy conversion component of a back-lit lighting device, in accordance with an embodiment of the present disclosure.

FIG. 9 depicts an example of a light source capable of providing light with enhanced or decreased melanopic lux to photopic lux ratio, in accordance with an embodiment of the present disclosure.

FIGS. 10A and 10B illustrate an example of a mechanism to manually convert an existing light source into a light source capable of providing light with enhanced or decreased melanopic lux to photopic lux ratio, in accordance with an embodiment of the present disclosure.

FIGS. 11A and 11B illustrate an alternate apparatus for converting an existing light source into a light source capable of providing light with enhanced or decreased melanopic lux to photopic lux ratio, in accordance with an embodiment of the present disclosure.

FIGS. 12-15 show measured spectrum and the associated Correlated Color Temperature (CCT), Duv, CRI Ra, R9, and M/P ratio for various energy conversion films used to generate bio-friendly light, in accordance with an embodiment of the present disclosure.

### DEFINITIONS

Melanopic lux: flux density, in melanopic lumens per m², weighted for the response of the melanopsin, i.e., weighted by a luminous efficiency function based on the action spectrum of melanopsin (or melanopic sensitivity function), which peaks at 480-490 nm but ranges beyond 460-520 nm.

Photopic lux: flux density, in lumens per m², delivered or received in the wavelength band 380-760 nm when weighted for the response of the human visual receptors.

Color rendering Index (CRI): a specification of the ability of a light to accurately render all colors as compared to a similar rendering by light from a blackbody emitter that has been heated to the equivalent color temperature. When not otherwise specified, CRI refers to the average color rendering index, Rₐ.

Correlated Color Temperature (CCT): a specification of color appearance of light that relates the color to that of a blackbody emitter that has been heated to a specified temperature, measured in degrees Kelvin (K).

Duv: the value of the Euclidean distance of a light color point from the blackbody curve on the 1975 CIE L*, u*, v* color space.

M/P ratio: ratio of melanopic lux to photopic lux.

### DETAILED DESCRIPTION

Recent interest in the biological effects of artificial light has led to further description of light for circadian performance. Whereas the photopic spectral sensitivity function peaks near 555 nm, the circadian spectral sensitivity function peaks at about 464 nm. The circadian function describes a biological suppression of the production of melatonin. The spectral response of the melanopsin receptors, the primary non-visual receptors responsible for signaling the suprachiasmatic nuclei in the brain, peaks at a wavelength in a range from 480 nm to 490 nm. The flux of light that is weighted for the melanopsin spectral sensitivity function has been called melanopic flux. Likewise, the flux associated with the circadian action spectrum, as determined by the production of melatonin, is referred to as circadian lumens (cirlm) or biolumens (blm). The illuminance associated with melanopic flux is referred to as equivalent melanopic lux (EML).

In addition to a metric of melanopic flux or melanopic lux, the characteristic of the relative quantity of melanopic light compared to photopic light is described by the melanopic ratio M/P, where M represents the melanopic lux and P represents photopic lux. A light with a high melanopic ratio will generally suppress the production of melatonin.

Insofar as artificial light is expected to be white to be psychologically pleasing, light sources with high melanopic flux or melanopic lux are expected have a relatively low Duv, requiring that a light spectrum that would be ideal for melanopic flux, and would otherwise appear blue-green, must be augmented with additional wavelengths to provide a pleasing white color. Since sources designed to provide white light with high melanopic content must sacrifice spectral characteristics that would provide higher photopic response, it can be expected that such high melanopic content light will be expected to provide lower luminous efficacy in order to achieve higher melanopic efficacy. Similarly, additional emission wavelengths are required to achieve good color rendering, so that both the luminous efficacy and the melanopic efficacy may be reduced by the production of an emission spectrum capable of high CRI.

Light quantity and quality have been described in the past in either radiometric terms, where the spectral contributions are considered equivalently through the full energy of the light, or in photometric terms, where the spectral contributions are appropriately weighted for the average human ocular response. For example, radiometric flux is typically given in watts (W), while the photometric flux is described in lumens (lm). As a result of the photometric weighting, light that is rich in blue or red components may have a reduced lumen content when compared with a radiometrically equivalent light that spectrally peaks near the wavelength of maximum photopic response.

Light visual quality is usually described by color, as characterized by the position of the light in the 1975 CIE Chromaticity Diagram, and by the ability to render visual colors, as characterized by the average Color Rendering Index (CRI), Rₐ. The color of light is particularly important when describing white light. The color coordinates of white light are given relative to the coordinates of a blackbody emission associated with a particular blackbody temperature as described by the Planckian locus. The corresponding correlated color temperature derives from that point on the Planckian locus with the smallest geometric distance to the coordinates of the light of interest. That distance, Duv, is an important metric of white light, since too large a distance indicates that the light will not be perceived as white.

The present disclosure provides a lighting device that provides light with a desired spectral composition such as, for example, light having high melanopic flux and which may be configured to stimulate alertness (e.g., for daytime use), or a low melanopic flux (i.e., for nighttime use).

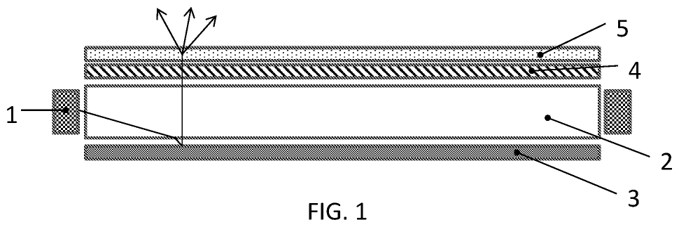

In one aspect of the present disclosure, the lighting device includes an edge-lit luminaire. FIG. 1 shows a structure of an edge-lit luminaire according to one implementation. In this embodiment, the luminaire comprises a light guide 2 that is edge-lit by one or more light sources 1 (e.g., incandescent sources, electric discharge sources, electroluminescent sources, etc.), an opaque reflector 3 that directs light to be emitted by the one or more light sources 1 through the light guide 2, and an energy conversion film 4 that converts at least a portion of a first spectrum emitted by the light sources 1 into a second spectrum. The second spectrum may have a high melanopic flux (e.g., for daytime use) or a low melanopic flux (e.g., for nighttime use). The luminaire may also comprise a diffuser 5 to disperse the light to be emitted by the luminaire. An example illumination system comprising an illuminations source, a waveguide, and one or more energy conversion films has been described in U.S. Pat. No. 8,664,624, which is incorporated herein by reference in its entirety.

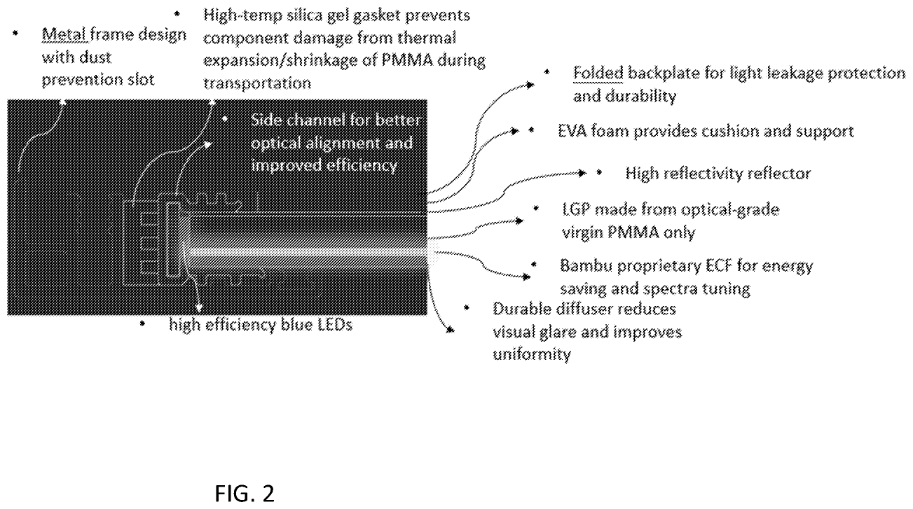

FIG. 2 shows a side-channel disposed inside the frame in accordance with some embodiments of the present disclosure. In some embodiments, the light source 1 is disposed inside a U-shaped bracket or channel 6, which is disposed inside the frame 8. In such embodiments, the relative position of the light source 1 and the other optical components including the light guide panel 2, the energy conversion film 4, the diffuser 5, the reflector 3, etc. can be fixed and the components aligned appropriately by using the U-shaped bracket 6. In other words, the U-shaped bracket 6 enables an effortless exchange of any of the optical components whenever one (or more) of the optical components needs to be replaced, without having to further align the components. In some embodiments, a high-temperature silica gel gasket 7 may be disposed between the U-shaped bracket 6 and the metal frame 8 to allow for expansion and/or contraction of the optical components during use without distorting the components or causing mis-alignment. The energy conversion film, in such embodiments, can be positioned between the light source and the corresponding edge of the light guide panel or over the front face of light guide panel.

Examples of incandescent sources include, without limitation, incandescent light bulbs, halogen lamps, various flash lamps, etc. Examples of electric discharge sources include, but are not limited to, arc lamps, flashtubes, mercury vapor lamps, sodium vapor lamps, metal-halide lamps, neon lamps, etc. Electroluminescent sources include, for example, light emitting diodes (LEDs), organic light-emitting diodes (OLEDs), various types of LASERs, etc. In various embodiments of the present disclosure, LEDs are used as light sources. It will, however, be understood that the lighting systems described herein can be suitably modified for use with other types of light sources.

In some embodiments, the one or more LEDs 1 can be a blue LED that emits light having a wavelength substantially in the range of 445-475 nm. In some embodiments, at least one LED 1 is mounted to a carrier such as a rigid, flexible, or semi-flexible printed circuit board to form an LED strip that can be mounted to an interior edge of fixture frame surrounding the light guide 2. For example, in an embodiment, LED strip 1 may include seven LEDs arranged in a single row with a fixed distance between each LED 1. It should be appreciated that any number and/or color of LEDs, arranged on a variety of carriers in a variety of circuit configurations (e.g., series-connected LEDs, parallel-connected LEDs) can be used without departing from the scope of the technology.

In some embodiments, each of the one or more LEDs 1 comprises a lens, such as a domed lens or a flat lens. In the structure shown in FIG. 1, a flat-top lens is preferable to enable a flush contact between the light guide 2 and the LED 1. For example, a domed lens in LED 1 may limit the number of photons that can be injected into the light guide 2 by limiting the proximity between the LED 1 and the light guide 2. In some embodiments LED 1 comprises a flat-top lens and the lighting device 100 is configured to obtain greater than 90% efficiency of capture of light emitted from the LED 1 into the light guide 2. In some embodiments LED 1 comprises a flat-top lens and the lighting device 100 is configured to obtain greater than 70% efficiency of capture of light emitted from the LED 1 into the light guide 2.

In an embodiment, light guide 2 is a rectangular panel formed of a transparent or translucent material such as acrylic, glass or quartz, configured to distribute and emit light emitted by LEDs 1. For example, light guide 2 is positioned in fixture frame such that edges of the frame are substantially adjacent to the light emitted by LEDs 1. Light emitted from LEDs 1 enters edges of the light guide 2 and is distributed throughout light guide 2. The light guide 2 typically incorporates a pattern of features designed to scatter guided optical modes of light transmission such that they are emitted from a front face of light guide 2 (i.e., the face of the light guide 2 adjacent the energy conversion film 4 to provide illumination. In some embodiments, a pattern of features is provided by surface deformation, such as etching. In other embodiments, a pattern of features is provided by embossing, molding, or otherwise including discrete prismatic structures within the light guide 2. In still other embodiments, a pattern of features is provided by printing a thin layer of coating material onto the desired areas of the light guide 2. The coating material may have substantially the same refractive index as the light guide panel 2 and one or more light scattering materials substantially dispersed therein. In some embodiments the preferred distance between the LED and the edge of the light guide is about 10 mm or less, about 5 mm or less, about 2 mm or less, about 1 mm or less, about 0.75 mm or less, about 0.5 mm or less, about 0.25 mm or less: about 0.1 mm or less, or about 0.05 mm or less. In some embodiments the preferred distance between the LED and the edge of the light guide is about 0.1 mm to about 5 mm, about 0.1 mm to about 2 mm, about 0.1 mm to about 1 mm, about 0.01 mm to about 1 mm, about 0.01 mm to about 0.05 mm, or about 0.01 mm to about 0.1 mm.

Opaque reflector 3 is formed of a reflective film or foil, and redirects any light emitted from a rear face of light guide 2 toward the front face. An intimate contact between the opaque reflector 3 and the back surface of light guide 2 (side farther from viewer) is preferred. The opaque reflector 3 can be attached to the back surface of the light guide 2 by applying a thin and/or fine line of non-absorbing adhesive running along the circumference of the back surface of the light guide 2. The adhesive should be selected to not interfere with light guide panel extraction patterns.

In an implementation a lighting device (e.g., luminaire) delivers a light with a melanopic ratio of at least 0.70 and a CRI Rₐ of at least 70 and a CCT of 4000-14000 K. In a preferred embodiment, the luminaire comprises LEDs with a peak emission at 460-475 nm and at least one energy conversion component that produces light in the range 475-780 nm.

In another implementation, a luminaire delivers light with an M/P ratio of no greater than 0.40, a CRI Rₐ of at least 70 and a CCT of 2200-4000 K. In a preferred embodiment, the luminaire comprises LEDs with a peak emission of 400-460 nm and at least one energy conversion component that produces light in the range 460-780 nm. In this case, the energy conversion component is designed to absorb a significant portion of the incident LED light and emit efficient emission at visible wavelengths greater than 500 nm, generally in the range 500-730 nm, with minimal light produced in the range 460-500 nm. As a result, LEDs with an emission of 400-460 nm are preferred, and the combination of dyes to achieve the desired converted spectrum must be significantly altered from that designed to produce light with a low M/P ratio.

In some embodiments, a lighting device according to the present disclosure has an energy conversion film that converts at least a portion of a first spectrum emitted by the LEDs into a second spectrum with an M/P ratio of no more than 0.40 (e.g., no more than 0.20), a CRI Rₐ of at least 70, and a CCT of 2500-3000 K. The luminaire may also comprise a diffuser to disperse the light to be emitted by the luminaire.

A high melanopic flux lighting device according to certain embodiments of the present disclosure may be configured to stimulate the ipRGC of a user. In some embodiments, the present disclosure includes a lighting device that provides visible illumination with enhanced emission in the range 460-520 nm with an M/P ratio of X1. In some embodiments, X1 is at least 0.7. In some embodiments, X1 is selected from any value from 0.9-1.3, for example, X1 may be from 1.0 to 1.2. For example, in various embodiments, X1 may be 0.7, 0.75, 0.8, 0.85, 0.9, 0.95, 1.0, 1.05, 1.1, 1.15, 1.2, 1.25, 1.3, or any value between any two of these values. The light produced by the lighting device is preferably perceived as white light by a human user. In some embodiments, the lighting device provides a CRI of at least 70, a |Duv| of less than 0.01, and a CCT in the range of 4000-14000 K. For example, in an embodiment, the lighting device may provide a CRI of 70, a |Duv| of 0.009 and a CCT in the range of 4000 K-14000 K. In an embodiment, the lighting device may provide a CRI of 75, a |Duv| of 0.009 and a CCT in the range of 4000 K-14000 K. In an embodiment, the lighting device may provide a CRI of 70, a |Duv| of 0.009 and a CCT in the range of 4000 K-14000 K. In an embodiment, the lighting device may provide a CRI of 80, a |Duv| of 0.009 and a CCT in the range of 4000 K-14000 K. In an embodiment, the lighting device may provide a CRI of 70, a |Duv| of 0.008 and a CCT in the range of 4000 K-14000 K. In an embodiment, the lighting device may provide a CRI of 75, a |Duv| of 0.008 and a CCT in the range of 4000 K-14000 K. In an embodiment, the lighting device may provide a CRI of 80, a |Duv| of 0.008 and a CCT in the range of 4000 K-14000 K. In an embodiment, the lighting device may provide a CRI of 80, a |Duv| of 0.01 and a CCT in the range of 4000 K-6200 K.

A low melanopic flux lighting device according to some embodiments of the present disclosure may be configured to reduce stimulation of the ipRGC of a user. In some embodiments, a lighting device provides visible illumination with reduced emission in the range 460-520 nm with an M/P ratio of X2, where X2 is less than X1. In some embodiments, X2 is less than 0.40, less than 0.30, or less than 0.20. In some embodiments, X2 may be any value from 0.10-0.40, for example, X2 may be from 0.15 to 0.35. Thus, in various embodiments, X2 may be 0.1, 0.15, 0.2, 0.25, 0.3, 0.35, 0.4, or any value between any two of these values. The light produced by the lighting device is preferably perceived as white light by a human user. In some embodiments, the lighting device provides a CRI of 70, a |Duv| of less than 0.01, and a CCT in the range 2200-4000 K. In some embodiments, the lighting device provides a CRI of 85, a |Duv| of 0.009 and a CCT in the range of 2200 K-2700 K.

In some embodiments, a lighting device according to the present disclosure provides visible illumination with enhanced emission in the range 460-520 nm with a M/P ratio of X1 wherein the illumination is produced by a system that comprises one or more LEDs, and at least one energy conversion film which is arranged and configured to convert light received from the one or more LEDs. The LEDs in some embodiments are chosen to emit in the range 450-475 nm so that any unconverted light will also contribute to the melanopic flux. Additional spectral components are produced by energy conversion using the energy conversion component. In some embodiments, the energy conversion component comprises fluorescent components that can absorb a portion of the LED light and produce additional luminance at longer wavelengths, as described in U.S. Pat. No. 8,415,642.

The energy conversion component may be a solid optical component, such as a plate, a prism, or a lens, or may be a film. The energy conversion component may be prepared by injection molding, extrusion, compression, or coating, or any combination of such processes.

The energy conversion component may contain one or more dyes, phosphors, or pigments, the combination of which may be tailored to produce light of the desired characteristics. Fluorescent materials are preferred over other types of luminescent pigments. The use of fluorescent materials to alter the spectrum of an emission source has been described in U.S. Pat. No. 8,163,201 and in U.S. Pat. No. 8,415,645, each of which is incorporated herein by reference in its entirety. A first fluorescent material must absorb at least a portion of the incident light provided by the LEDs, and then must efficiently emit a substantial amount of the absorbed energy at longer wavelengths. The light so converted can be subsequently absorbed by a second fluorescent material that can then emit the absorbed light at still longer wavelengths. Additional dyes and pigments can be used in such a fashion to obtain a desired emission spectrum from the luminaire. For some embodiments, design of the energy conversion component must deliver as much light as possible in the wavelength range 470-500 nm while still providing enough light at longer wavelengths to achieve a perceptually white color and adequate color rendering. In particular, diisobutyl 4,10-dicyanoperylene-3,9-dicarboxylate (LUMOGEN® F Yellow 083) is an effective dye to provide significant and efficient emission in the range 470-500 nm.

The energy conversion components may also comprise a carrier medium. The carrier medium may be rigid glass, such as a borosilicate or quartz glass, or may be a polymeric carrier such as an acrylic resin, a polyvinyl chloride, a polycarbonate, a styrene, a polyurethane, a polyester, or other similar polymer. Depending on the nature of the preparation of the energy conversion component, the carrier may include other components such as antioxidants, surfactants, scatterers, hindered amine light stabilizers (HALS), and other similar additives.

In some embodiments, the energy conversion components are polymeric films including one or more dyes, phosphors, or pigments. The one or more dyes, phosphors, pigments, etc. are generally homogeneously distributed within the body of the films. Such energy conversion components are referred to herein as energy conversion films (ECFs).

In some example embodiments, an ECF which contains diisobutyl 4,10-dicyanoperylene-3,9-dicarboxylate (e.g., available as LUMOGEN® F Yellow 083). In some embodiments, use of diisobutyl 4,10-dicyanoperylene-3,9-dicarboxylate provides maximum amount of light in the range 470-500 nm. In some embodiments, the ECF may further include other fluorescent dyes, for example, 3,4,9,10-perylene tetracarboxylic acid bis(2,6-diisopropyl) anilide (e.g., available as LUMOGEN® F Orange 240) and 1,6,7,12-tetraphenoxy-N,N′-di(2,6-diisopropylphenyl)-3,4:9,10-perylenediimide (e.g., available as LUMOGEN® F Red 305). In some embodiments, these other fluorescent dyes may provide yellow-red emission. In further embodiments, the ECF does not include 3-cyanoperylene-9,10-dicarboxylic acid 2′,6′-diiosopropylanilide (e.g., available as LUMOGEN® F Yellow 170) since this dye may absorb significant emission in the desired wavelength range.

In some embodiments, a lighting device according to the present disclosure provides visible illumination with reduced emission in the range 460-520 nm with a M/P ratio of X2 wherein the illumination is produced by a system that comprises one or more LEDs, and at least one energy conversion film which is arranged and configured to convert light received from the one or more LEDs. The LEDs in some embodiments are chosen to emit in the range 400-460. In some embodiments, the EFC contains 3-cyanoperylene-9,10-dicarboxylic acid 2′,6′-diiosopropylanilide (e.g., LUMOGEN® F Yellow 170).

The matrix into which the fluorescent components of the ECF are dispersed can comprise of polymers or glasses. Polymers are particularly useful due to the greater range of available materials from which to sub-select so as to form a homogeneous mixture of the energy conversion element and the polymer. Acceptable polymers include acrylates, polyurethanes, polycarbonates, polyvinyl chlorides, polystyrene, silicone resins, and other common polymers. Materials with glass transition temperatures above the normal operating temperature of the material are particularly useful. The polymer matrix must be capable of preventing aggregation of the fluorescent components, i.e., creating a homogeneous mixture of the dye and the polymer, or a solid-state solution of the dye and polymer. Fluorescent component aggregation is one of the possible causes of loss of fluorescence efficiency and in certain cases can also contribute to photolytic degradation. If the molecules of the fluorescent components are allowed to form aggregates and microcrystalline forms, instead of a solid-state solution, the dye molecules excited by electromagnetic radiation can undergo static self-quenching, effectively lowering the yield of fluorescence, and therefore lowering the efficiency of energy conversion. In some fluorescent components, high concentrations can lead to enhanced photo-degradation, through efficient energy migration to chemically active traps or through self-sensitized photo-oxidation stimulated by triplet states accessed primarily from excimers.

Additional components may be added to the formulation to facilitate the dissolution and coating of the energy conversion photoluminescent material and the polymer, such as dispersants, wetting agents, defoamers, rheology modifiers, and leveling agents. Dispersants, wetting agents, defoamers, and leveling agents may each be oligomeric, polymeric, or copolymeric materials or blends containing surface-active (surfactant) characteristic blocks, such as, for example, polyethers, polyols, or polyacids. Examples of dispersants include acrylic acid-acrylamide polymers, or salts of amine functional compound and acid, hydroxyfunctional carboxylic acid esters with pigment affinity groups, and combinations thereof, for example DISPERBYK®-180, DISPERBYK®-181, DISPERBYK®-108, all from BYK-Chemie, and TEGO® Dispers 710 from Degussa GmbH. Wetting agents are surfactant materials, and may be selected from among polyether siloxane copolymers, for example, TEGO® Wet 270, non-ionic organic surfactants, for example TEGO® Wet 500, and combinations thereof. Suitable rheology modifiers include polymeric urea urethanes and modified ureas, for example, BYK® 410 and BYK® 411 from BYK-Chemie®, and fumed silicas, such as CAB-O-SIL® M-5 and CAB-O-SIL® EH-5. Deaerators and defoamers may be organic modified polysiloxanes, for example, TEGO® Airex 900. Leveling agents may include polyacrylates, polysiloxanes, and polyether siloxanes. Quenchers of singlet molecular oxygen can also be added, such as 2,2,6,6-tetramethyl-4-piperidone and 1,4-diazabicyclo[2.2.2]octane. Each such material must be tested to assure that it does not cause aggregation of the energy conversion photoluminescent materials, does not quench the fluorescence of the energy conversion photoluminescent materials, and that the material does not react, either thermally or photochemically, with the energy conversion photoluminescent materials.

In an embodiment, the energy conversion component, includes from about 25%-45% of binder resin, about 50%-70% of liquid carrier, 0%-2% dispersing agent, 0%-2% rheology modifying agent, 0%-2% photostabilizer, 0%-2% de-aerating agent, 0%-2% wetting agent, and 0.01%-0.2% photoluminescent fluorescent material.

The luminaire may also comprise additional optical components to efficiently direct and disperse the light generated into a useful spatial pattern. In particular, at least one reflector may be used to direct light to a preferred viewing hemisphere. Additionally, light emitted from the front face of the luminaire can be dispersed using one or more diffusers, lenses, prisms, or other more complex optical components.

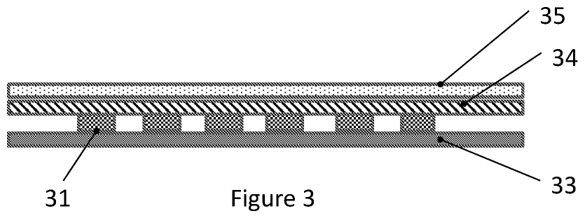

In another aspect of the present disclosure, the lighting device includes back-lit luminaire. FIG. 3 shows a structure of an edge-lit luminaire according to one implementation. In this embodiment, the luminaire comprises one or more light sources 31 (e.g., incandescent sources, electric discharge sources, electroluminescent sources, etc.), an opaque reflector 33 that directs light to be emitted by the one or more light sources 31 to a viewing hemisphere, and an energy conversion film 34 that converts at least a portion of a first spectrum emitted by the light sources 31 into a second spectrum. The second spectrum may have a high melanopic flux (e.g., for daytime use) or a low melanopic flux (e.g., for nighttime use). The luminaire further includes a diffuser 35 to disperse the light converted by the energy conversion film 34 into the viewing hemisphere. Various components that can be used in the edge-lit luminaire shown in FIG. 1 can be suitably modified for use in the back-lit luminaire shown in FIG. 3.

In another implementation, the principal elements of the luminaire providing a high melanopic flux and a luminaire providing a low melanopic flux are combined. In one example a luminaire can be constructed with two separate emitting surfaces, so that one half or portion of the luminaire emits light with high melanopic flux, while another half or portion emits light with low melanopic flux. In some such embodiments, the luminaire may be treated as two devices that have been joined and are connected by a power source and controls that allow switching between the two emissive states.

Providing both lights in the same device so as to use a common emission surface requires an ability to separate the sources of the spectra of light from the light distribution system. The use of a light guide distribution provides a means to uniform, low glare light provisioning. While previous constructions have shown the value of using energy conversion films at the exit face of the luminaire, the desire to provide two different light emission characteristics from one emissive surface prevents this positioning of the energy conversion component for the inventive design. In particular, the production of high melanopic flux in one state and low melanopic flux in a second state cannot be accomplished with a single energy conversion component or film containing dyes due to crosstalk between the emission systems required to produce each state of light. Likewise, separate but adjacent films suffer from the same problem.

For example, a luminaire design with a first film producing light with a high melanopic flux and a second film that produces light with a low melanopic flux would only produce low melanopic flux light, since the film designed to convert light in the range 450-500 nm to longer wavelengths would perform that function on any incident light, including that with high melanopic flux produced by the first film. Likewise, if the order of the films were reversed such that the first film produced light with low melanopic flux and the second film produced high melanopic flux, then either the second film would never see enough deeper blue light to produce high melanopic flux light so that only light with low melanopic flux could be produced, or the second film would produce high melanopic flux light even in cases when only low melanopic flux would be desired.

As a result, it may be preferable to produce the desired light characteristics by the respective sources before injection of the light into a light guide. In an embodiment of this implementation, a square luminaire comprises a square light guide wherein two opposing sides of the luminaire light guide can used to provide one characteristic of light and the remaining two opposed sides can be used to provide the second characteristic of light. In some embodiments, the need for uniform distribution of light from each of the lighting systems can be provided by a luminaire with four-fold symmetry provided by a square luminaire design.

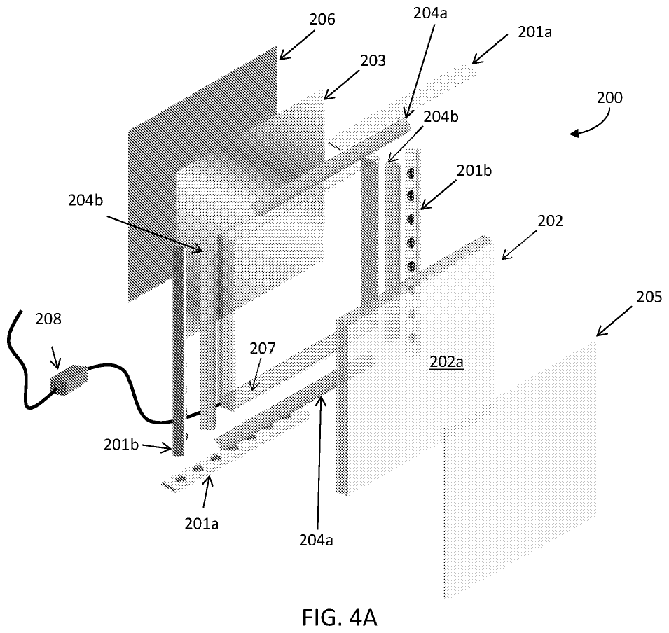

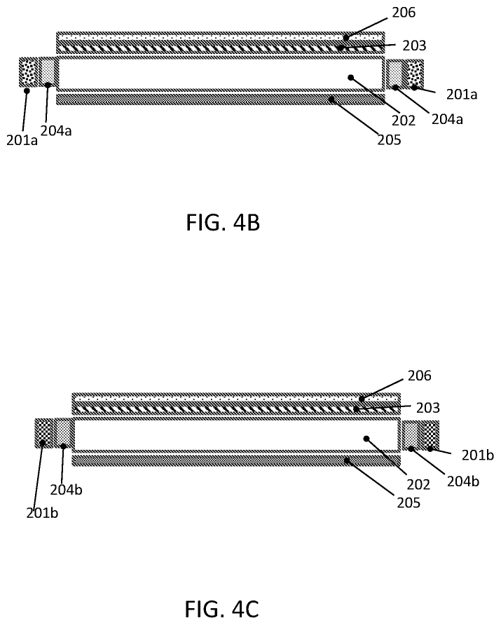

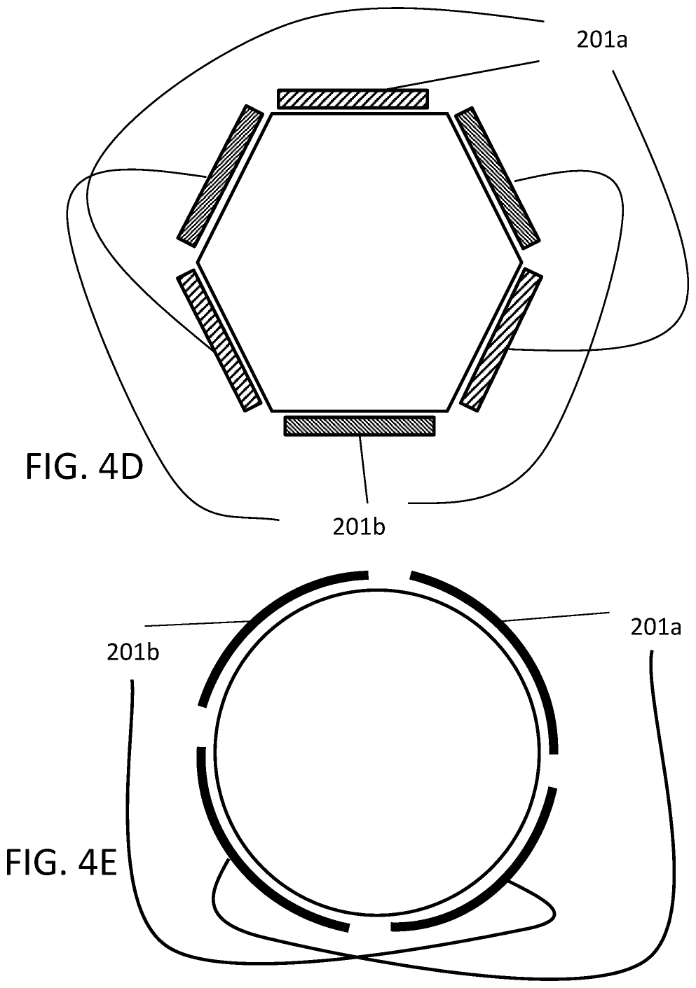

One way of separately providing two types of light into the luminaire is to provide the appropriate energy conversion component with an appropriate LED source at the entrance face of the light into the edge of the light guide. Each of these energy conversion components comprises one or more fluorescent components uniformly incorporated into a block or slab of polymer or glass in concentrations useful to generate the desired converted spectrum when illuminated by the appropriate source light. The block or slab may additionally be covered on at least two sides with a reflective element or coating to direct the light toward the injection face of the light guide. The block or slab may also be covered on at least two sides with a protective film or coating to inhibit the penetration of oxygen into the energy conversion component. Additionally, the block or slab may be covered with a directional reflective film or coating on the side immediately adjacent to the edge of the light guide, to prevent the excitation of dyes by the “wrong” set of LEDs. For example, it would be undesirable for the daytime LED source to activate the nighttime energy conversion component, and vice versa (i.e., LEDs 201b activating 204a in FIG. 4A, described in detail elsewhere herein).

FIGS. 4A-4C show an edge-lit lighting device 200 (luminaire) according to an example embodiment of the present disclosure which can provide light with either high melanopic flux or low melanopic flux. In this embodiment, lighting device 200 includes a light guide panel 202 which is configured to be edge-lit by at least two separate sets of LEDs, a first set 201a which is configured to provide the source light to produce the light with high melanopic flux and a second set 201b which is configured to provide the source light to produce the light with low melanopic flux. Light guide panel 202, in some embodiments, may be shaped as a generally square panel as shown having a square light emitting surface 202a. In some embodiments, the first set of LEDs 201a includes two LED strips that may be positioned along a first pair of opposing edges of light guide panel 202 and the second set of LEDs includes two LED strips 201b that may be positioned along a second pair of opposing edges of light guide panel 202.

In some embodiments, LED strips 201a and LED strips 201b are configured to emit different wavelengths of light. For example, in some embodiments, LED strips 201a include LEDs which emit light with a peak emission at 445-475 nm, while LED strips 201b include LEDs which emit light with a peak emission at 420-440 nm. In some embodiments, the two LED strips 201a and 201b both include LEDs configured to emit same wavelengths of light, e.g., with a same peak emission at 400-460 nm.

In some embodiments, at least one energy conversion film (ECF) is positioned between each of LED strips 201a, 201b and the edges of light guide panel 202. In some embodiments, the at least one energy conversion film includes first ECF strips 204a positioned between each of the LED strips 201a and a corresponding edge of the light guide panel 202, and second ECF strips 204b positioned between each of the LED strips 201b and a corresponding edge of the light guide panel 202. In some embodiments, first ECF strips 204a are configured to convert at least a portion of a spectrum emitted by LED strips 201a into a first converted spectrum with, for example, an M/P ratio of at least 0.70 (e.g., 0.7, 0.8, 0.9, 1.0, 1.1, 1.2, etc.) , a CRI Rₐ of at least 70, and a CCT of 4000-14000 K. In some embodiments, second EFC strips 204b are configured to convert at least a portion of a spectrum emitted by LED strips 201b into a second converted spectrum with, for example, an M/P ratio of no more than 0.40 (e.g., no more than 0.20), a CRI Ra of at least 70, and a CCT of 2200-4000 K. In some embodiments, EFC strips 204a contains a different fluorescent dye composition and/or amount than EFC strips 204b in order to achieve the different M/P ratios.

In further embodiments, lighting device 200 may further include a reflecting layer 203 configured to be positioned to face a back surface of light guide 202 that is opposite light emitting surface 202a. Reflecting layer 203 in some embodiments is configured to reflect at least a portion of light towards light emitting surface 202a. Lighting device 200 may also include a diffusion layer 205 configured to be positioned on light emitting surface 202a and configured to scatter light emitted from light emitting surface 202a. Light guide panel 202 may therefore be positioned between reflecting layer 203 and diffusion layer 205. In still further embodiments, lighting device 200 may include a backing layer 206 positioned behind reflecting layer 203 such that reflecting layer 203 is positioned between backing layer 206 and light guide panel 202. In some embodiments, frame 207 may be provided to house components of lighting device 200, including light guide panel 202, LED strips 201a, 202b, and ECF strips 204a, 204b. In some embodiments, LED strips 201a, 201b may be mounted along the internal edges of frame 207. In further embodiments, frame 207 may be made of metal (e.g., aluminum, copper, etc.), for example, and be configured to help dissipate heat from LED strips 201a, 202b.

The dimensions of the lighting device 200 are not particularly limited and are determined by factors such as, for example, design constraints based on the space in which the lighting device is to be used, materials being used to construct various components of the lighting device, commercial availability or manufacturability of some or all of the components of the lighting device, etc. Common dimensions of such devices may include, without limiting the scope of this disclosure, 1′×1′, 2′×2′, 3′×3′, 1′×4′, and 2′×4′.

It will be appreciated that while examples with a square shaped edge-lit luminaire are discussed herein, other regular polygonal shapes such as, for example, hexagon, octagon, etc. can be implemented with modifications based on an understanding of the concepts disclosed herein. Similarly, a circular luminaire may also be implemented. Examples of a hexagonal edge-lit luminaire and a circular edge-lit luminaire are shown in FIGS. 2D and 2E (which show the plan view of the hexagonal and circular luminaire respectively). It must be noted that while only the LED strips 201a/201b are shown in FIGS. 2D and 2E for convenience, each of the LED strips include the corresponding ECF as well. It must also be noted that while only two types of LED strips are shown in FIGS. 2D and 2E, more types of LED strips may be included. For example, FIG. 2D can include three different types of LED strips disposed on each pair of opposing edges of the light guide panel 202 while maintaining the symmetry. Likewise, in FIG. 2E, while only 2 pairs of LED strips are shown, any number (e.g., 1, 2, 3, 4, 5, 6, etc.) of pairs of LED strips can be disposed symmetrically opposite around the circumference of the light guide panel to potentially obtain the corresponding number of output spectra.

Some of the geometries such as the hexagonal or circular shapes allow more than 2 types of spectra, e.g., using more than 2 types ECF configured to provide different output spectra. Lighting devices with geometries that provide different (e.g., more than two) output spectra may be used for applications such as, for example, providing yellow light in a semiconductor fabrication clean room; providing a red-light for photography development room; providing different colored lights for entertainment purposes; providing light with spectrum matching ambient light in airplanes; etc. In such applications, the lighting devices may include more than two types of ECFs configured to provide more than two types of output spectra and the LED strips corresponding to each type of ECF may be selectively turned on at a desired time to provide the desired output spectrum.

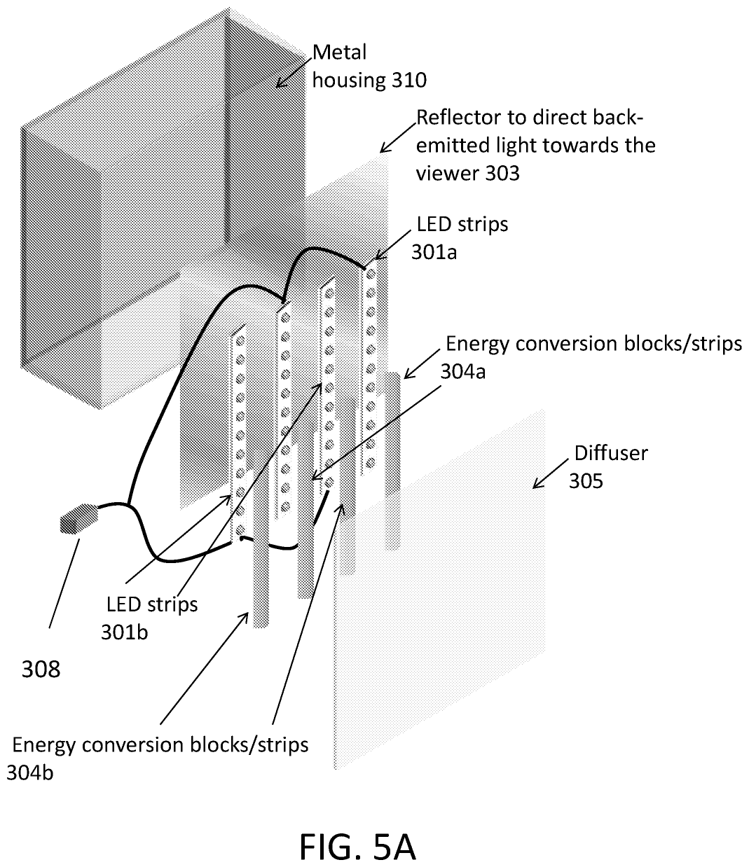

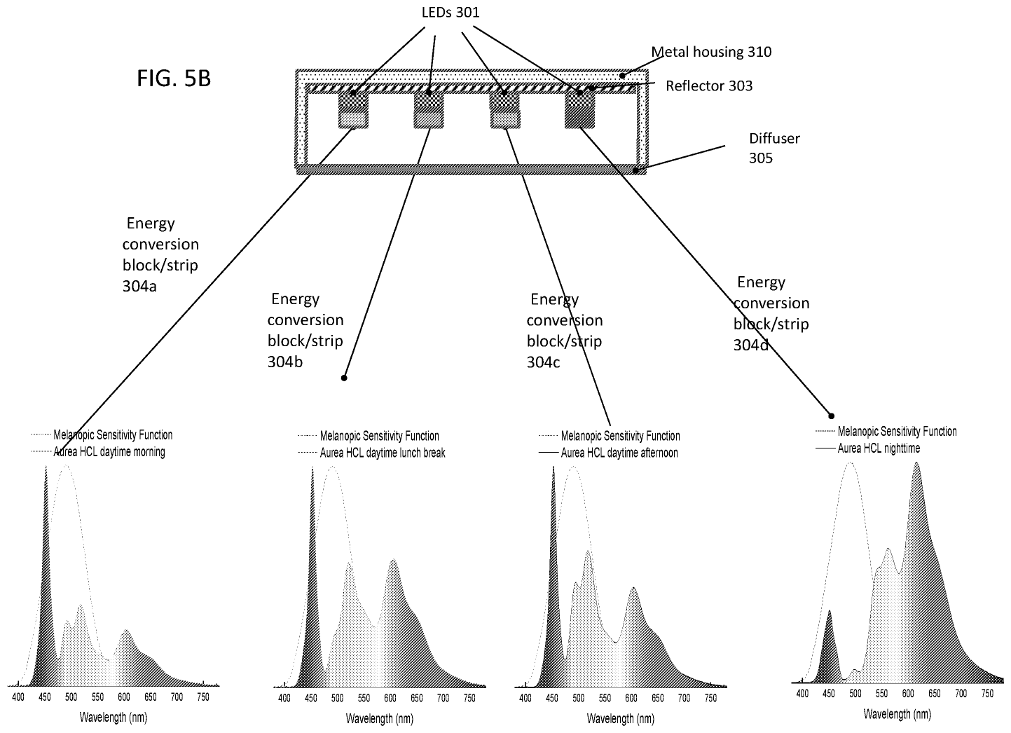

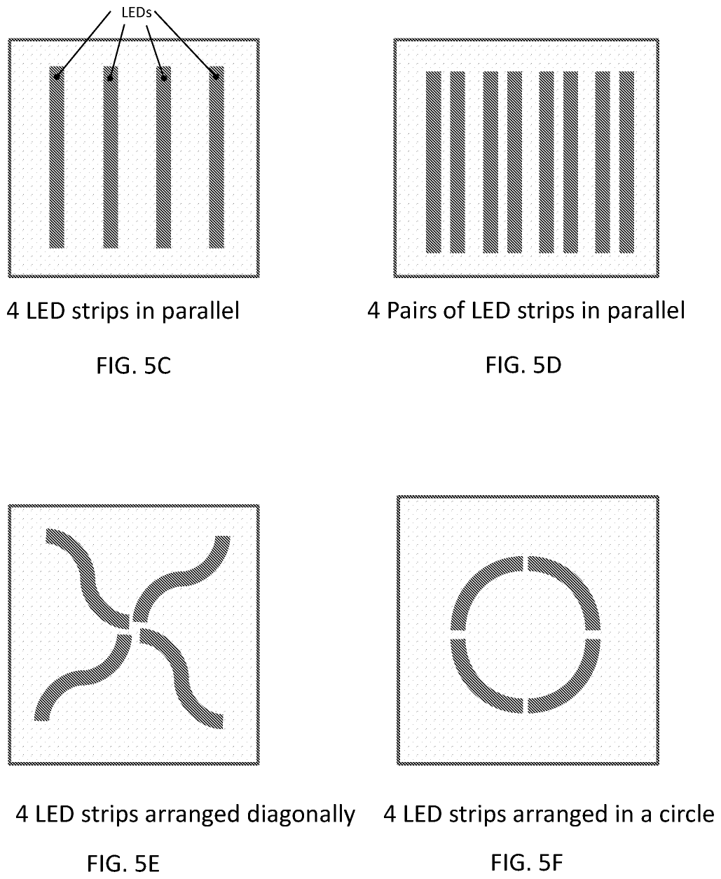

FIG. 5A shows a back-lit lighting device 300 (luminaire) according to an example embodiment of the present disclosure which can provide light with either high melanopic flux or low melanopic flux. In this embodiment, lighting device 300 includes a first set 301a which is configured to provide the source light to produce the light with high melanopic flux and a second set 301b which is configured to provide the source light to produce the light with low melanopic flux. The first and second set 301a/301b are disposed on a reflector 303, configured to direct back-emitted light by the first and second sets toward the viewing hemisphere through the diffuser 305.

In some embodiments, LED strips 301a and LED strips 301b are configured to emit different wavelengths of light. For example, in some embodiments, LED strips 301a include LEDs which emit light with a peak emission at 445-475 nm, while LED strips 301b include LEDs which emit light with a peak emission at 420-440 nm. In some embodiments, the two LED strips 301a and 301b both include LEDs configured to emit same wavelengths of light, e.g., with a same peak emission at 400-460 nm.

In some embodiments, at least one energy conversion film (ECF) is positioned between each of LED strips 301a, 301b and the back surface of the diffuser 305. In some embodiments, the at least one energy conversion film includes first ECF strips 304a positioned between each of the LED strips 301a and the back surface of the diffuser 305, and second ECF strips 304b positioned between each of the LED strips 301b and the back surface of the diffuser 305. In some embodiments, first ECF strips 304a are configured to convert at least a portion of a spectrum emitted by LED strips 301a into a first converted spectrum with, for example, an M/P ratio of at least 0.70 (e.g., 0.7, 0.8, 0.9, 1.0, 1.1, 1.2, etc.) , a CRI Ra of at least 70, and a CCT of 4000-14000 K. In some embodiments, second EFC strips 304b are configured to convert at least a portion of a spectrum emitted by LED strips 301b into a second converted spectrum with, for example, an M/P ratio of no more than 0.40 (e.g., no more than 0.20), a CRI Rₐ of at least 70, and a CCT of 2200-4000 K. In some embodiments, EFC strips 304a contains a different fluorescent dye composition and/or amount than EFC strips 304b in order to achieve the different M/P ratios.

The reflecting layer 303 in some embodiments is configured to reflect at least a portion of light towards the viewing hemisphere through the diffuser 305. In some embodiments, lighting device 300 may include a backing layer (not shown) positioned behind reflecting layer 303 such that reflecting layer 303 is positioned between backing layer 306 and the diffuser 305. In some embodiments, a frame or a metal housing 310 may be provided to house components of lighting device 300, including LED strips 301a, 302b, and ECF strips 304a, 304b and the diffuser 305.

The dimensions of the lighting device 300 are not particularly limited and are determined by factors such as, for example, design constraints based on the space in which the lighting device is to be used, materials being used to construct various components of the lighting device, commercial availability or manufacturability of some or all of the components of the lighting device, etc. Common dimensions of such devices may include, without limiting the scope of this disclosure, 1′×1′, 2′×2′, 3′×3′, 1′×4′, and 2′×4′.

Advantageously, the back-lit structure allows for more than 2 types of spectra, e.g., using more than 2 types ECF configured to provide different output spectra irrespective of the geometry of the device. Lighting devices that provide different (e.g., more than two) output spectra may be used for applications such as, for example, providing yellow light in a semiconductor fabrication clean room; providing a red-light for photography development room; providing different colored lights for entertainment purposes; providing light with spectrum matching ambient light in airplanes; etc. In such applications, the lighting devices may include more than two types of ECFs configured to provide more than two types of output spectra and the LED strips corresponding to each type of ECF may be selectively turned on at a desired time to provide the desired output spectrum. One advantage of using ECF to generate specific spectrum of light over using a filter is that while a filter absorbs and dissipates unwanted wavelengths, ECF converts all light into desired wavelengths. Thus, ECF may provide improved efficiency.

An example of a back-lit lighting device that can produce light with several different output spectra is shown in FIG. 5B. The lighting device, as shown in FIG. 5B, includes 4 different types of ECFs, 304a, 304b, 304c and 304d, to generate 4 different output spectra by disposing the 4 different types of ECFs, 304a, 304b, 304c and 304d, on different LED strips within the lighting device. It will be appreciated that while the figure shows the LED strips to be of the same type (i.e., 301), different types of LEDs (i.e., having different emission spectra with different peak emission wavelength(s)) may also be used to provide specific spectra. It will also be appreciated that while 4 different ECFs are shown in FIG. 5B, more or less number of ECF types may be used to provide more or less different spectra tailored to specific applications. The different number of spectra that can be generated using such a device is limited only by space constraints and the availability of different types of ECFs and/or light sources that can generate different output spectra.

It will be appreciated that while the figures show generally square shaped back-lit luminaires, other shapes such as, rectangular, circular, ellipsoidal, hexagonal, etc., can be implemented with modifications based on an understanding of the concepts disclosed herein. Moreover, the placement of the LED strips within the shape of the lighting device is not particularly limited so long as the light emitted from the diffuser 305 into the viewing hemisphere is generally uniform. FIGS. 5C-5F shows various examples of positioning of LED strips within the lighting device. For example, as shown in FIG. 5C, the LED strips can be positioned along a length (or a width) of the lighting device, with the two kinds of LED strips (or two different types of ECFs) being positioned alternately. In another example, as shown in FIG. 5D, several pairs of LED strips are positioned along a length (or a width) of the lighting device, and each pair includes two different types of LED strips (or two different types ECFs disposed on the LED strips). It will be appreciated that instead of pairs, triplets, quartets, etc. may also be used. In yet other examples, as shown in FIGS. 5E and 5F, the LED strips may be arranged diagonally or in a circular pattern so as to increase the uniformity of the light emitted by the lighting device.

Hybrid/Tunable Lighting Devices

Referring back to FIGS. 4A-4C, in some embodiments, the edge-lit lighting device 200 further includes a power supply 208 which is configured to provide power to LED strips 201a, 202b. In some embodiments, lighting device 200 may be switched between a first state (e.g., high melanopic flux state or daytime use), wherein power supply 208 provides power to LED strips 201a but not to LED strips 201b, and a second state (e.g., low melanopic state or nighttime use), wherein power supply 208 provides power to LED strips 201b but not to LED strips 201a.

In some embodiments, lighting device 200 may be configured to gradually transition from the first state to the second state and vice versa. In some embodiments, lighting device 200 may be programmable such that lighting device 200 transitions between the two states at predetermined times which may be set by a user. For example, in an embodiment, the programing of lighting device 200 is achieved using a microcontroller. The microcontroller, in an embodiment, may use pulse-width modulation (PWN) to output an analog voltage. The PWM signal is run through a low pass filter that is set up for a frequency that is substantially lower than that of the PWM, resulting in the square wave of the PWM to be converted to a constant voltage that is the average of the voltage from the PWM. From the low pass filter, the signal is sent through an operational amplifier to amplify the voltage. The output of the operational amplifier is then connected to the input of LED strips 201a, 201b. The microcontroller can then be used to change the voltage provided to LED strips 201a, 201b to obtain a smooth shift from high melanopic flux state to a low melanopic flux state (or vice versa) over a set period at a set time.

In an embodiment, the microcontroller is connected to a network, e.g., the Internet. In such embodiments, the microcontroller can be controlled and/or programmed remotely to change the set period and the set time at which the transition between high melanopic flux state and a low melanopic flux state is to occur, e.g., based on syncing the clock of the microcontroller with a central server, or changing the set time based on local sunrise/sunset times. In an embodiment, the set time can also be changed based on, e.g., local weather conditions to allow more or less melanopic flux for longer or shorter period of time depending on the local weather.

Similarly, referring back to FIG. 5A, in some embodiments, the back-lit lighting device 300 further includes a power supply 308 which is configured to provide power to LED strips 301a, 302b. In some embodiments, lighting device 300 may be switched between a first state (e.g., high melanopic flux state or daytime use), wherein power supply 308 provides power to LED strips 301a but not to LED strips 301b, and a second state (e.g., low melanopic flux state or nighttime use), wherein power supply 308 provides power to LED strips 301b but not to LED strips 301a.

In some embodiments, lighting device 300 may be configured to gradually transition from the first state to the second state and vice versa. In some embodiments, lighting device 300 may be programmable such that lighting device 300 transitions between the two states at predetermined times which may be set by a user. For example, in an embodiment, the programing of the lighting device 300 is achieved using a microcontroller. The microcontroller, in an embodiment, may use pulse-width modulation (PWN) to output an analog voltage. The PWM signal is run through a low pass filter that is set up for a frequency that is substantially lower than that of the PWM, resulting in the square wave of the PWM to be converted to a constant voltage that is the average of the voltage from the PWM. From the low pass filter, the signal is sent through an operational amplifier to amplify the voltage. The output of the operational amplifier is then connected to the input of the LED strips 301a, 301b. The microcontroller can then be used to change the voltage provided to the LED strips 301a, 301b to obtain a smooth shift from high melanopic flux state to a low melanopic flux state (or vice versa) over a set period at a set time.

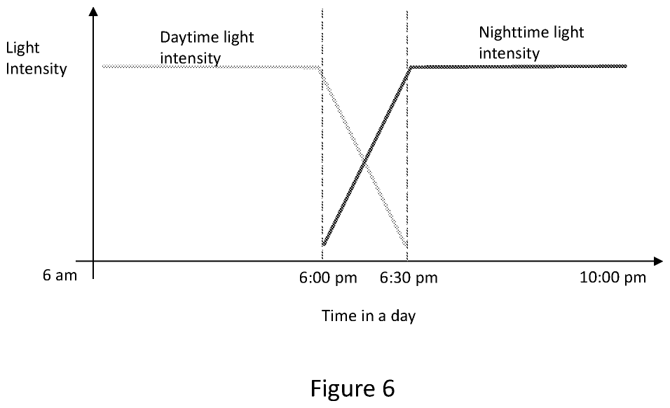

FIG. 6 is a graph showing the light intensity over time emitted by a lighting device in accordance with an embodiment of the present disclosure. According to an example scenario wherein a luminaire, e.g., lighting device 200 or lighting device 300, is configured to emit light with a high M/P ratio (e.g., “Daytime Light”) and light with a low M/P ratio (e.g., “Nighttime Light”). According to this scenario, the luminaire is programmed to:
Between a wake time (e.g., 6 am) and 6 pm, power on LED strips 201a at 100% intensity;
Between 6 pm and 6:30 pm, gradually decrease LED strips 201a from 100% intensity to 0% intensity;
Between 6 pm and 6:30 pm, gradually increase LED strips 201b from 0% intensity to 100% intensity;
Between 6:30 pm and a sleep time (e.g., 10:00 pm), keep LED strips 201b powered at 100% intensity.
   It should be appreciated that the above scenario is given for illustration only, and that lighting device 200 may be programmed in other ways and times depending on the user's preferences. It will also be appreciated that similar programming/tuning can be achieved in the back-lit embodiments, e.g., by selectively powering the LED strips corresponding to one or more energy conversion components, to obtain a desired light spectrum.

In embodiments where the lighting device provides light with more than two different output spectra (e.g., similar to the device shown in FIG. 5B), the microcontroller may be suitably modified to, e.g., selectively produce one spectrum of light at a time, gradually transition from one spectrum to another, etc.

Swappable Energy Conversion Component

In the tunable devices discussed herein, the net intensity of light provided by the luminaire may be decreased because only half (or in some implementations even less) of the possible LEDs are utilized at a given time. Thus, in applications where high net intensity is desirable, it may be preferable to keep all LEDs in an ON state to obtain a high intensity. For such applications, the structure of luminaire discussed with respect to FIG. 1 may be more desirable. The tuning of output spectrum, in such embodiments, is obtained by changing the energy conversion component 4.

The energy conversion component 4, in some embodiments, can be changed manually or using a motorized mechanism which can be automated and programmed based on conditions such as, for example, the time of the day, lighting environments, or personal preference. Both the electrical control system for the light source(s) and the control system for the motor can be connected to a network (e.g., the Internet), and programmed to optimize the intensity of light, duration, timing, and pattern based on synchronizing the internal clock of the lighting system with a central server, or local sunrise/sunset times and/or weather conditions.

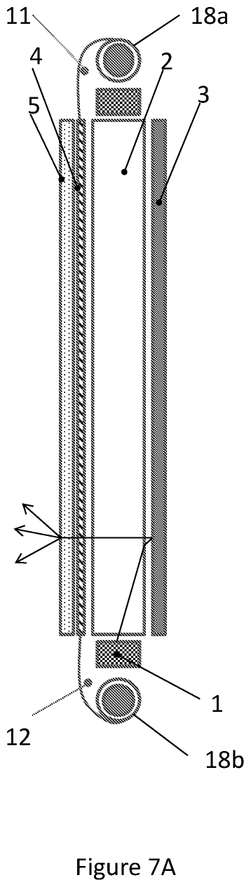

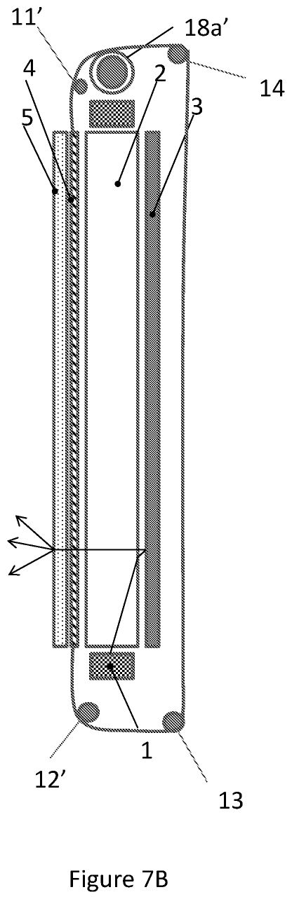

FIG. 7A shows an example of an apparatus used for changing an energy conversion component of an edge-lit lighting device 400 in accordance with an embodiment of the present disclosure. Various components of the lighting device 400 are essentially the same as those of the lighting device shown in FIG. 1, with the addition of the mechanism 18 for changing the energy conversion film 4. In an embodiment, as shown in FIG. 7A, the mechanism 18 includes a roller 18a on which the energy conversion firm (ECF) 4 is wrapped. A portion of the ECF 4 is stretched across the light guide panel 2. The portion of ECF 4 being stretched across the light guide panel 2 can be changed by turning the roller such that the ECF 4 moves across the light panel 2 to expose a different portion of the ECF 4 to the light guide panel 2. A counter-roller 18b may be included opposite the roller 18a to collect the portion of the ECF 4 that is moved away from the light guide panel 2. Additionally, in some embodiments, guide-rollers 11 and 12 may be included for guiding the ECF 4 along a track so as to prevent mechanical scraping of the ECF 4 and ensuring a smooth movement of the ECF 4 over the light guide panel 2. In such an embodiment, a slot (not shown) and a track (not shown) may be provided within the frame of the lighting device 400 for the ECF 4 to move in an out of the frame.

In some embodiments, the roller 18a and counter-roller 18b may be provided with a rotating crank (not shown) to rotate the corresponding rollers manually so as to change the portion of ECF 4 being exposed to the light guide panel 2. In other embodiments, the roller 18a and counter-roller 18b may be motorized, and the motor (not shown) may be powered through a switch allowing a user to rotate the roller 18a and the counter-roller 18b when desired. In yet other embodiments, the roller 18a and the counter-roller 18b may be motorized, and the motor is controlled using a controller which automatically initiates the rotation of the roller 18a and the counter-roller 18b based on a programmed scheduled to expose different portions of the ECF 4 to the light guide panel as desired. In some embodiments, movement of the ECF is created by friction between the ECF and the drive roller. In some embodiments, the movement of the ECF is created by a cog or similar spoked wheeled engaging holes, slots or other such physical characteristics on the ECF structure.

FIG. 7B shows an alternative mechanism for changing the portion of ECF 4 being exposed to the light guide panel 2. As shown in FIG. 7B, the alternative mechanism includes only one roller 18a′ and guide-rollers 11′, 12′, 13 and 14 which guide the ECF 4 to move over the light guide panel 2. In such an embodiment, the roller 18a′ may be provided with a crank (not shown), a motor with a switch or a motor with a controller similar to the embodiment disclosed elsewhere herein.

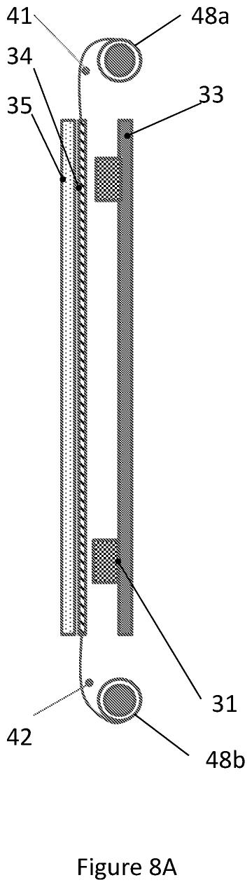

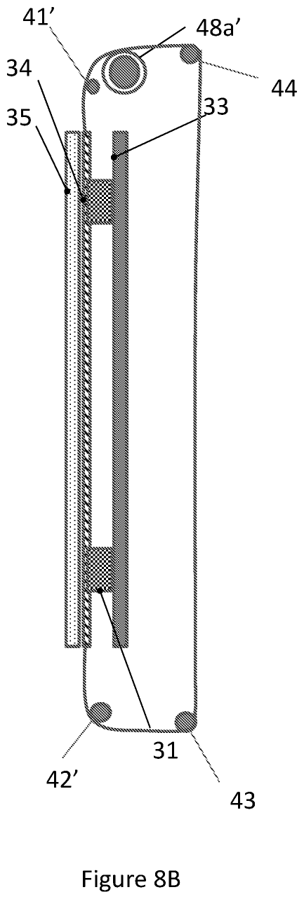

FIG. 8A shows an example of an apparatus used for changing an energy conversion component of a back-lit lighting device 500 in accordance with an embodiment of the present disclosure. Various components of the lighting device 500 are essentially the same as those of the lighting device shown in FIG. 3, with the addition of the mechanism 48 for changing the energy conversion film 34. In an embodiment, as shown in FIG. 8A, the mechanism 48 includes a roller 48a on which the energy conversion firm (ECF) 34 is wrapped. A portion of the ECF 34 is stretched across surface of the lighting device 500. The portion of ECF 34 within the exit surface of the lighting device 500 can be changed by turning the roller 48a such that the ECF 34 moves across the exit surface to expose a different portion of the ECF 34 to the light emitted by the LEDs 31 and reflected by the reflector 33. A counter-roller 48b may be included opposite the roller 48 to collect the portion of the ECF 34 that is moved away from the exit surface. Additionally, guide-rollers 41 and 42 may be included for guiding the ECF 34 along a track so as to prevent mechanical scraping of the ECF 34 and ensuring a smooth movement of the ECF 34 over the exit surface. In such an embodiment, a slot (not shown) and a track (not shown) may be provided within the frame of the lighting device 500 for the ECF 34 to move in an out of the frame.

In some embodiments, the roller 48a and counter-roller 48b may be provided with a rotating crank (not shown) to rotate the corresponding rollers manually so as to change the portion of ECF 34 being exposed to the light guide panel 32. In other embodiments, the roller 8a and counter-roller 48b may be motorized, and the motor (not shown) may be powered through a switch allowing a user to rotate the roller 48a and the counter-roller 48b when desired by turning the switch ON or OFF. In yet other embodiments, the roller 48a and the counter-roller 48b may be motorized, and the motor is controlled using a controller which automatically initiates the rotation of the roller 48a and the counter-roller 48b based on a programmed scheduled to expose different portions of the ECF 34 to the exit surface as desired. In some embodiments, the movement of the ECF is created by friction between the ECF and the drive roller. In some embodiments, the movement of the ECF is created by a cog or similar spoked wheel engaging holes, slots, or other such physical characteristics on the ECF structure.

FIG. 8B shows an alternative mechanism for changing the portion of ECF 34 being exposed to the light guide panel 32. As shown in FIG. 8B, the alternative mechanism includes only one roller 8a′ and guide-rollers 41′, 42′, 43 and 44 which guide the ECF 34 to move over the light guide panel 32. In such an embodiment, the roller 48a′ may be provided with a crank (not shown), a motor with a switch or a motor with a controller similar to the embodiment described with reference to FIG. 8A.

In the implementations where different portions of the ECF are exposed to the light guide panel as desired, the ECF may be formed as a continuous film with different portions having different compositions allowing each portion to output a different spectrum. For example, in an embodiment, the ECF may include a first portion configured to provide light with high melanopic flux and a second portion configured to provide light with a low melanopic flux. The ECF may be formed as continuous film with the first portion and the second portion alternately placed immediately adjacent to each other. In some embodiments, the first portion and the second portion are separated by a third portion without any energy conversion elements (e.g., dyes, fluorophores, phosphors, etc.). Additional portions with several (e.g., 2, 3, 4, 5, 6, 7, etc.) different ECF configurations are contemplated.

In embodiments where the mechanism for changing the portion of ECF being exposed to the light guide panel is controlled using a controller, the controller may be programmed in a similar manner disclosed elsewhere herein, e.g., to provide different light spectra at different times of the day. For example, instead of providing power to different sets of LEDs provided with different ECFs at different times, the roller 8a and 8b (or 8a′) or 48a and 48b (or 48a′) may be rotated to expose different portions of ECFs to the light guide panel at different times.

Advantageously, embodiments with swappable or movable ECFs allow for easy exchange of ECFs in case the ECF is worn or no longer efficient in converting the light.

Manually Switchable Lighting

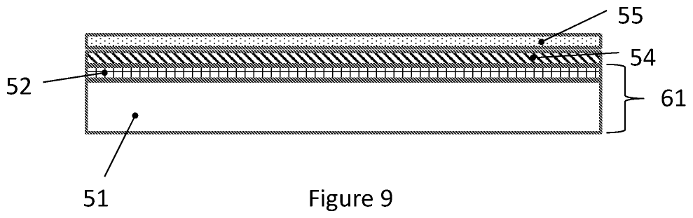

FIG. 9 depicts an example of a light source capable of providing light with enhanced or decreased melanopic lux to photopic lux ratio. In this embodiment, the lighting device comprises a light source 51, and an energy conversion film 54 that converts at least a portion of a first spectrum emitted by the light source into a second spectrum with a melanopic ratio of at least 0.70, a CRI Ra of at least 70, and a CCT of 4000-14000 K. In an embodiment, the light source 51 is included in a light guide panel 61 having a frame 52. The energy conversion film 54 is disposed over the exit surface of the light source 51 such that the light emitted by the light source 51 passes through the energy conversion film before exiting to the viewing hemisphere to reach a user.

In a second implementation, a lighting device delivers light with an M/P ratio of no greater than 0.40, a CRI Rₐ of at least 70 and a CCT of 2200-4000 K. In a preferred embodiment, the lighting device comprises a light source 51 and at least one energy conversion component 54 that produces light in the range 460-780 nm. The energy conversion film 54 is disposed over the exit surface of the light source 51 such that the light emitted by the light source 51 passes through the energy conversion film before exiting to the viewing hemisphere to reach a user. In this case, the energy conversion component is designed to absorb a significant portion of the incident light and emit efficient emission at visible wavelengths greater than 500 nm, generally in the range 500-730 nm, with minimal light produced in the range 460-500 nm.

The lighting device may also comprise a diffuser 55 to disperse the light to be emitted by the lighting device. An example illumination system comprising one or more energy conversion films has been described in U.S. Pat. No. 8,664,624, which is incorporated herein by reference in its entirety.

In some embodiments, the light source includes a white light source 51 such as, for example, fluorescent lamps, LED-based white lights, halogen lamps, incandescent light bulbs, flash lamps, etc. In some embodiments, the white light source 51 is commercially available. In some embodiments, the light source is preinstalled in a fixture such as, in a residential or in a commercial building. In some embodiments, the light source may include more than one white light source In some embodiments, the emission characteristics of the light source include: CCT in the range of 2700-6000 K, CRI greater than 85 and luminosity of about 2500-4000 lumens for about 4 sq.ft, to about 5000-6000 at about 8 sq.ft.

In some embodiments, the light source may include a housing (not shown) in which the white light source is positioned. The housing may have a frame 62 outlining the exit surface of the light source. The light source may further include a reflector (not shown) and a diffuser (not shown) in some embodiments. In some embodiments, the frame 62 is quadrangular or circular in shape, but other shapes are contemplated.

The energy conversion component 54 may be a solid optical component, such as a plate, a prism, or a lens, or may be a film. The energy conversion component may be prepared by injection molding, extrusion, compression, or coating, or any combination of such processes.

In some embodiments, an energy conversion film (ECF) is positioned over (or inside an exit surface of) the frame 52. In some embodiments, the energy conversion film 54 includes a first ECF configured to convert at least a portion of a spectrum emitted by the white light source 51 into a first converted spectrum with, for example, an M/P ratio of at least 0.70 (e.g., 0.7, 0.8, 0.9, 1.0, 1.1, 1.2, etc.), a CRI Rₐ of at least 70, and a CCT of 4000-14000 K. In some embodiments, the energy conversion film 54 includes a second EFC configured to convert at least a portion of a spectrum emitted the white light source 51 into a second converted spectrum with, for example, an M/P ratio of no more than 0.40 (e.g., no more than 0.20), a CRI Rₐ of at least 70, and a CCT of 2200-4000 K.

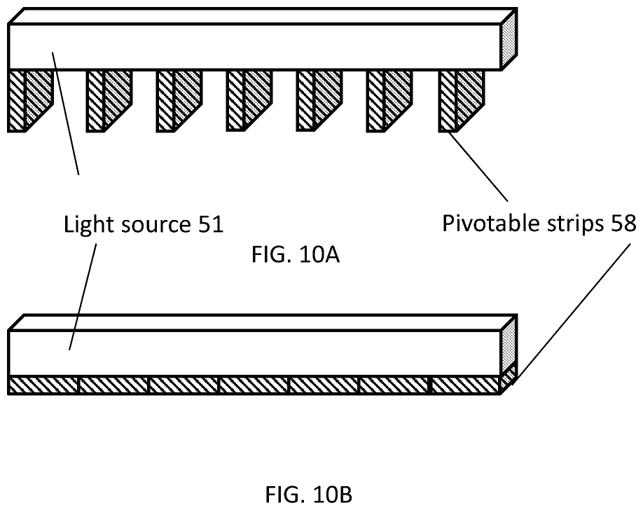

FIGS. 10A and 10B illustrate an apparatus for converting an existing light source into a biofriendly light source in accordance with an embodiment of the present disclosure. In an embodiment, the energy conversion film 54 may be mounted on a transparent substrate such as an acrylic sheet and formed into strips which can be pivotably attached to the light source.

As shown in FIG. 10A, when the strips 58 of energy conversion film 54 are perpendicular to an existing light source 51, the light from the light source 51 does not pass through the EC film, and thus reaches the user unaltered. On the other hand, when the strips 58 of the energy conversion film are turned (i.e., pivoted) to be parallel to the exit surface light source 51 source, i.e., as shown in FIG. 10B, such that each of the EC strips 58 covers a portion of the exit surface of the light source 51, the light emitted by the light source 51 passes through the strips 58 of the energy conversion film before reaching the user. In other words, the spectrum of the light emitted by the light source 51 is altered by the strips 58 of the energy conversion film before reaching the user. The user, therefore, receives light based on the energy conversion film selected.

For example, in residential buildings, the energy conversion film may be selected to have a composition that results in a low melanopic flux or lux. In such embodiments, the strips 58 can be pivoted from the perpendicular position shown in FIG. 10A to the parallel position shown in FIG. 10B at, e.g., sunset, to provide suitably bio-friendly light. The pivoting action may be provided manually, e.g., using a mechanism similar to window blinds or a pivoting flange, or using a motorized assembly which can pivot the individual strips 58. On the other hand, in, for example, office buildings, where it may be important to provide light that can stimulate alertness during the day, the energy conversion film may be selected to have a composition that results in a high melanopic flux or lux.

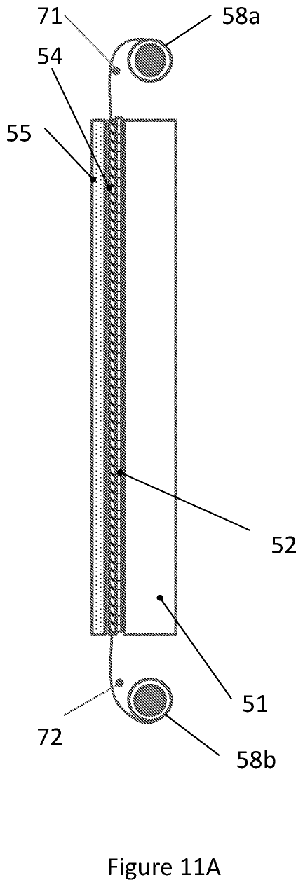

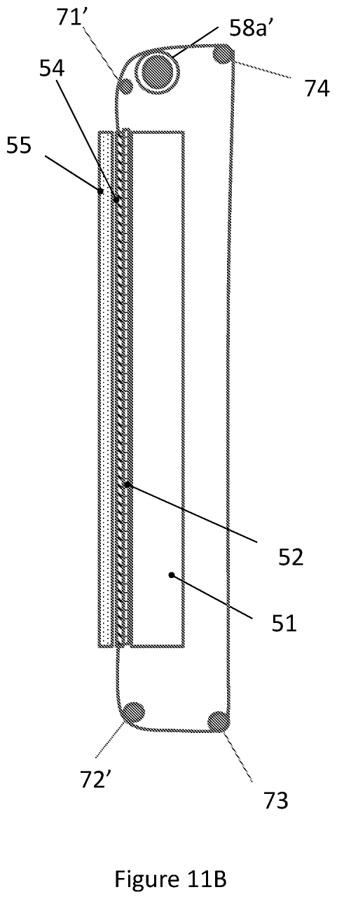

FIGS. 11A and 11B illustrate an alternate apparatus for converting an existing light source into a biofriendly light source in accordance with an embodiment of the present disclosure. In an embodiment, the frame 52 provided to light source 51 is replaced by a frame with a slot, in which the energy conversion film 54 can be removably positioned, e.g., by sliding the film in or out of the slot. This mechanism of sliding the EC film into a predefined slot to enable conversion of light spectrum of an existing light source may also be accomplished using a motorized assembly whereby by a roll of EC film with suitable composition may be unrolled or retracted using a motorized roller to pass through the slot as shown in FIGS. 11A and 11B.

In an embodiment, as shown in FIG. 11A, the mechanism 58 includes a roller 58a on which the energy conversion film (ECF) 54 is wrapped. A portion of the ECF 54 is stretched across the exit surface of the light source 51 over (or through a slot in) the frame 52. The portion of ECF 54 being stretched across the exit surface can be changed by turning the roller 58a such that the ECF 54 moves across the frame 52 to expose a different portion of the ECF 54 to the light exit surface. A counter-roller 58b may be included opposite the roller 58a to collect the portion of the ECF 54 that is moved away from the light guide panel 61. Additionally, guide-rollers 71 and 72 may be included for guiding the ECF 54 along a track so as to prevent mechanical scraping of the ECF 54 and ensuring a smooth movement of the ECF 54 over the frame 52. In such an embodiment, a slot (not shown) and a track (not shown) may be provided within the frame 52 of the lighting device for the ECF 54 to move in an out of the frame 52. In some embodiments, the roller 58a and counter-roller 58b may be provided with a rotating crank (not shown) to rotate the corresponding rollers manually so as to change the portion of ECF 54 being exposed to the exit surface of the light source 51. In other embodiments, the roller 58a and counter-roller 58b may be motorized, and the motor (not shown) may be powered through a switch allowing a user to rotate the roller 58a and the counter-roller 58b when desired. In yet other embodiments, the roller 58a and the counter-roller 58b may be motorized, and the motor is controlled using a controller which automatically initiates the rotation of the roller 58a and the counter-roller 58b based on a programmed scheduled to expose different portions of the ECF 54 to the light guide panel as desired. In some embodiments, movement of the ECF is created by friction between the ECF and the drive roller. In some embodiments, the movement of the ECF is created by a cog or similar spoked wheeled engaging holes, slots or other such physical characteristics on the ECF structure.

FIG. 11B shows an alternative mechanism for changing the portion of ECF 54 being exposed to the exit surface. As shown in FIG. 11B, the alternative mechanism includes only one roller 58a′ and guide-rollers 71′, 72′, 73 and 74 which guide the ECF 54 to move over the light guide panel 61. In such an embodiment, the roller 58a′ may be provided with a crank (not shown), a motor with a switch or a motor with a controller similar to the embodiment disclosed elsewhere herein.

In the implementations where different portions of the ECF are exposed to the light guide panel as desired, the ECF may be formed as a continuous film with different portions having different compositions allowing each portion to output a different spectrum. For example, in an embodiment, the ECF may include a first portion configured to provide light with high melanopic flux and a second portion configured to provide light with a low melanopic flux. The ECF may be formed as continuous film with the first portion and the second portion alternately placed immediately adjacent to each other. In some embodiments, the first portion and the second portion are separated by a third portion without any energy conversion elements (e.g., dyes, fluorophores, phosphors, etc.). Additional portions with different ECF configurations are contemplated.

It will be understood that while the embodiments described herein include the ECF between the LED strips and the diffuser, it is also possible to rearrange the diffuser to be between the ECF and the LED strips. In such embodiments, it may be preferable to provide a protective layer, e.g., a sheet of glass or other transparent material, above the ECF such that the ECF is between the protective layer and the diffuser, and the protective layer forms the outermost surface of the lighting device exposed to the viewing hemisphere. The protective layer may be advantageous in preventing wear and tear of the ECF.

### EXAMPLE 1

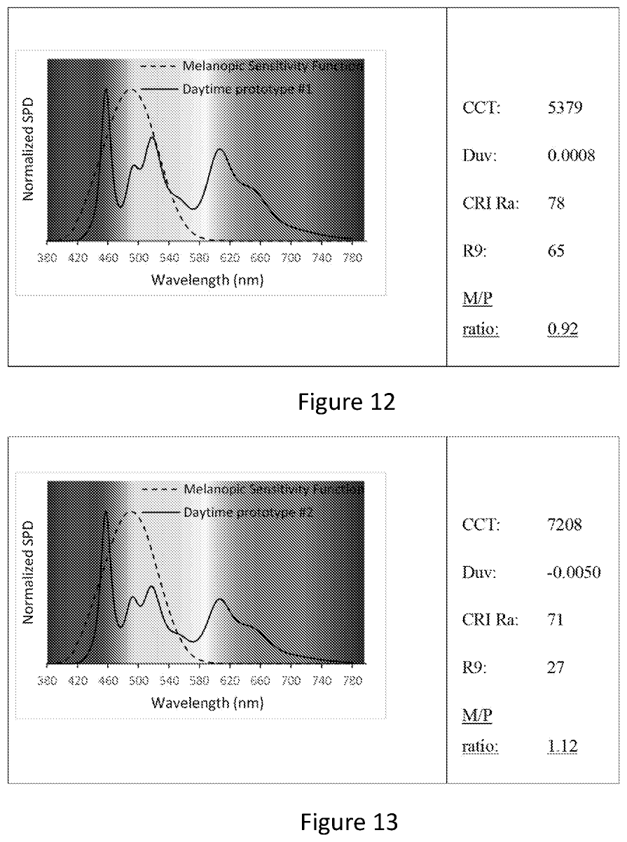

In one example, a 195 mm×195 mm 6-watt edge-lit LED panel was fitted with an energy conversion film to generate bio-friendly light. The panel comprised 30 blue LEDs with a peak wavelength of 460 nm located along 2 opposing edges of a light guide that served as the emissive surface of the LED panel. The energy conversion film was prepared by coating a 12″×12″ section of 0.010″ thick mylar substrate using a 12″ wide Bird Film Applicator with a 0.010″ clearance. The coating fluid comprised a polymer binder (ELVACITE® 2014 acrylic resin), 2 fluorescent dyes (LUMOGEN® F Yellow 083 and LUMOGEN® F Red 305), additives (PLASTHALL® 670, Titanium dioxide (TiO₂), FOAMEX® N, TEGO® Wet 270), and solvents (toluene and dioxolane). The total solid content of the coating fluid is 40% by weight, and the fluorescent dye concentrations in the dry film are 0.084% (w/w) of LUMOGEN® F Yellow 083 and 0.023% of LUMOGEN® F Red 305, respectively. Titanium dioxide (TiO₂) is included at a concentration of 1% to create desirable light scattering in the film to eliminate total internal reflection (TIR) and increase light conversion efficiency. The coated wet film is first dried in an oven at 40° C. for 4 hours and then moved to an oven at 80° C. for at least 4 hours. The dry film is trimmed and placed between the light guide panel and a diffuser sheet inside the 195 mm×195 mm LED panel to produce a lighting device with high melanopic content. The spectrum of the panel is measured using a Konica Minolta CS2000 spectroradiometer focused on the front surface of the diffuser of the light panel at normal incidence. The measured spectrum and the associated Correlated Color Temperature (CU), Duv, CRI Ra, R9, and M/P ratio are shown in FIG. 12.

### EXAMPLE 2

Example #2 is similar to Example #1, except that the concentration of LUMOGEN® F Yellow 083 in the dry film is reduced to 0.067%, producing a lighting device with high melanopic content. The measured spectrum and the associated CCT, Duv, CRI Ra, R9, and M/P ratio are shown in FIG. 13.

### EXAMPLE 3

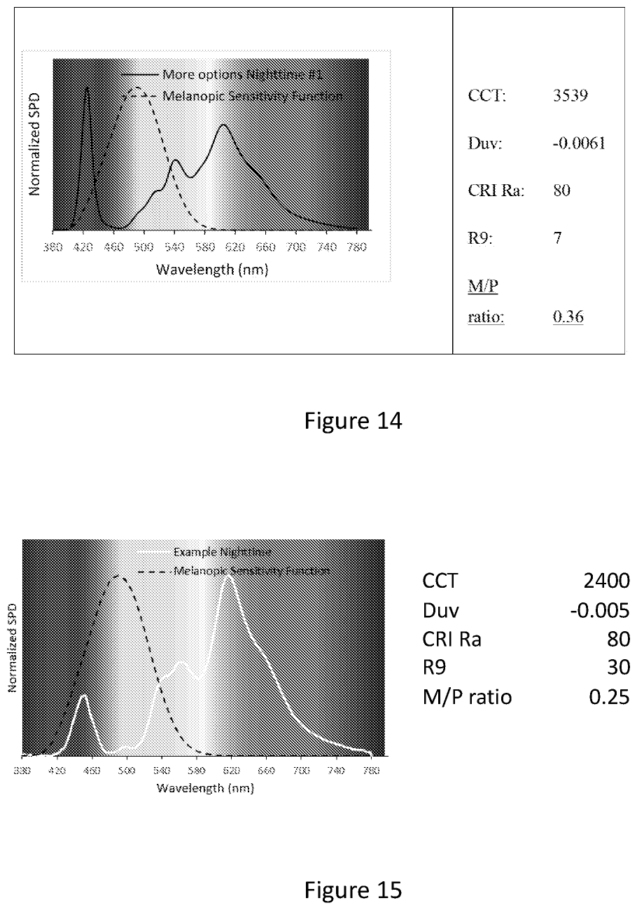

In another example, a 195 mm×195 mm 6-watt edge-lit LED panel was fitted with energy conversion films to generate bio-friendly light. The panel comprised 30 blue LEDs with a peak wavelength of 420 nm located along 2 opposing edges of a light guide that served as the emissive surface of the LED panel. The energy conversion film was coated on a 6″×12″ section of 0.010″ thick mylar substrate using a ½″×16″ Wire Wound Mayer Rod with a #60 wire. The coating fluid is composed of a polymer binder (NEOCRYL® B735), 3 fluorescent dyes (LUMOGEN® F Yellow 083, LUMOGEN® F Orange 240, and LUMOGEN® F Red 305), additives (TiO₂, BYK® 310, BYK® 356), and solvents (toluene and dioxolane). The total solid content is 30%, and the fluorescent dye concentrations in the dry film are 0.263% (ww) of LUMOGEN® F Yellow 083, 0.0260% of LUMOGEN® F Orange 240, and 0.0270% of LUMOGEN® F 305 Red. Titanium dioxide (TiO₂) is included at a concentration of 2.103% to create desirable light scattering in the film to eliminate TIR and increase light conversion efficiency. The coated wet film is first dried in an oven at 40° C. for 4 hours and then moved to an oven at 80° C. for at least 4 hours. The dry film is trimmed and placed between the light guide panel and LED strips along the opposing edges of the light guide panel to produce a lighting device with low melanopic content. The spectrum of the panel is measured using a Konica Minolta CS2000 spectroradiometer focused on the front surface of the diffuser of the light panel at normal incidence. The measured spectrum and associated CCT, Duv, CRI Ra, R9, and M/P ratio are shown in FIG. 14.

### EXAMPLE 4

In another example, a 195 mm×195 mm 6-watt edge-lit LED panel was fitted with energy conversion films to generate bio-friendly light. The panel comprised 60 blue LEDs with a peak wavelength of 460 nm located along all 4 edges of a light guide that served as the emissive surface of the LED panel. A first energy conversion film was extruded at 5 mil thickness using an SXT pilot extruder. 3 types of dyes and a scatter agent were first compounded into master batches in pellets form with concentrations of 0.6%, 0.6%, 0.2%, 2% for Yellow 083, Yellow 170, Red 305, and TiO₂, respectively. The master batches were then blended with polyester pellets at a ratio of 12.45%:8.33%:5.43%:8%:65.79% (Yellow 083:Yellow 170:Red 305:TiO₂:Polyester) for extrusion. The extrusion was performed at temperature of 525 F. All materials are pre-dried at 180 F before extrusion. The extruded film is trimmed and placed between the light guide panel and LED strips placed along first two opposing edges of the light guide panel.

A second energy conversion film was prepared by coating a 12″×12″ section of 0.010″ thick mylar substrate using a 12″ wide Bird Film Applicator with a 0.010″ clearance. The coating fluid comprised a polymer binder (ELVACITE® 2014 acrylic resin), 2 fluorescent dyes (LUMOGEN® F Yellow 083 and LUMOGEN® F Red 305), additives (PLASTHALL® 670, Titanium dioxide (TiO₂), FOAMEX® N, TEGO® Wet 270), and solvents (toluene and dioxolane). The total solid content of the coating fluid is 40% by weight, and the fluorescent dye concentrations in the dry film are 0.084% (w/w) of LUMOGEN® F Yellow 083 and 0.023% of LUMOGEN® F Red 305, respectively. Titanium dioxide (TiO₂) is included at a concentration of 1% to create desirable light scattering in the film to eliminate total internal reflection (TIR) and increase light conversion efficiency. The coated wet film is first dried in an oven at 40° C. for 4 hours and then moved to an oven at 80° C. for at least 4 hours. The dried film is trimmed and placed between light guide panel and LED strips placed along second two opposing edges of the light guide panel.

When the LED strips placed along the first two opposing edges were powered, the lighting device produced light with low melanopic content, with the measured spectrum and associated CCT, Duv, CRI Ra, R9, and M/P ratio shown in FIG. 12. When the LED strips placed along the second two opposing edges were powered, the lighting device produced light with high melanopic content, with a measured spectrum and associated CCT, Duv, CRI Ra, R9, and M/P ratio shown in FIG. 13.

### EXAMPLE 5

In one example, a commercial 2 ft×4 ft 34-watt back-lit 4000K white LED troffer was fitted with equal numbers of 450 nm blue LEDs, and then fitted with energy conversion films to generate bio-friendly light. The panel comprised 48 to 72 blue LEDs with a peak wavelength of 450 nm in one strip positioned length-wise symmetrically about a central axis of the emissive surface of the LED panel. A first energy conversion film was extruded at 5 mil thickness using an SXT pilot extruder. 3 types of dyes and a scatter agent were first compounded into master batches in pellets form with concentrations of 0.6%, 0.6%, 0.2%, 2% for Yellow 083, Yellow 170, Red 305, and TiO₂, respectively. The master batches were then blended with polyester pellets at a ratio of 12.45%:8.33%:5.43%:8%:65.79% (Yellow 083:Yellow 170:Red 305:TiO₂:Polyester) for extrusion. The extrusion was performed at temperature of 525 F. All materials were pre-dried at 180 F before extrusion. The extruded film is trimmed and placed along the interior curved surface of the diffuser to cover the entire emission area.

### EXAMPLE 6

In another example, 1′×4′ 28-watt edge-lit LED panels were retrofit with energy conversion films to generate bio-friendly light. The panel comprised 192-384 blue LEDs with a peak wavelength of 450-455 nm located along 2 opposing edges of a light guide that served as the emissive surface of the LED panel. The energy conversion film was extruded at 20-25 mil thickness using an extruder. Two types of dyes and a scatter agent were first compounded into a masterbatch with clear polycarbonate in pellets form with concentrations of 0.1050%, 0.0450%, 1.9525% for Yellow 083, Red 305, and TiO₂, respectively. The masterbatch was then blended with clear polycarbonate pellets at a ratio of 4.2:95.8% (masterbatch:Polyester) for extrusion. The extruded film is trimmed and placed between the light guide panel and a diffuser sheet inside the LED panel to produce a lighting device with low melanopic content. The spectrum of the retrofit panel is measured using a Stellarnet bluewave spectrometer with a CR2 cosine receptor at a distance of 1″ above the light panel surface pointing to the center of the illuminating surface at normal incidence. The measured spectrum and associated CCT, Duv, CRI, and M/P ratio are listed in Table 1.

### EXAMPLE 7

In another example, 1′×4′ 28-watt edge-lit LED panels were retrofit with energy conversion films to generate bio-friendly light. The panel comprised 192-384 blue LEDs with a peak wavelength of 450-455 nm located along 2 opposing edges of a light guide that served as the emissive surface of the LED panel. The energy conversion film was extruded at 20-25 mil thickness using an extruder. Three types of dyes and a scatter agent were first compounded into a masterbatch with clear polycarbonate in pellets form with concentrations of 0.3375%, 0.2950%, 0.0650%, 0.7250% for Yellow 083, Yellow 170, Red 305, and TiO₂, respectively. The masterbatch was then blended with clear polycarbonate pellets at a ratio of 4.2:95.8% (masterbatch:Polyester) for extrusion. The extruded film is trimmed and placed between the light guide panel and a diffuser sheet inside the LED panel to produce a lighting device with low melanopic content. The spectrum of the retrofit panel is measured using a Stellarnet bluewave spectrometer with a CR2 cosine receptor at a distance of 1″ above the light panel surface pointing to the center of the illuminating surface at normal incidence. The measured spectrum and associated CCT, Duv, CRI, and M/P ratio are listed in Table 1.

### EXAMPLE 8

In another example, a press out (4″ in diameter 22 mil in thickness) was created from a 2″×2″ 4-step injection molded color chip using hot press. The press-out was then placed inside a 1′×4′ 28-watt edge-lit LED panels to generate bio-friendly light. The panel comprised 192-384 blue LEDs with a peak wavelength of 450-455 nm located along 2 opposing edges of a light guide that served as the emissive surface of the LED panel. Three types of dyes and a scatter agent were used in the injection molded process with concentrations of 0.0026%, 0.0017%, 0.0013%, 0.0801% for Yellow 083, Yellow 170, Red 305, and TiO₂, respectively. The spectrum of the retrofit panel is measured using a Stellarnet bluewave spectrometer with a CR2 cosine receptor at a distance of 1″ above the light panel surface pointing to the center of the illuminating surface at normal incidence. The measured spectrum and associated CCT, Duv, CRI, and M/P ratio are listed in Table 1.

TABLE 1

| Example | M/P | | | | |
|---|---|---|---|---|---|
| # | ratio | CCT | CRI | Duv | Features |
| #6 | 1.20 | 5800 | 80 | 0.0110 | Suitable for daytime use; High |
| | | | | | M/P ratio to promote |
| | | | | | alertness; |
| #7 | 0.30 | 2400 | 80 | 0.0000 | Suitable for use before |
| | | | | | bedtime; Low M/P ratio to |
| | | | | | promote restfulness |
| #8 | 0.80 | 5000 | 90 | 0.0000 | Suitable for daytime use with |
| | | | | | high CRI; Visually pleasing |

We claim:

1. A lighting device that provides visible illumination with enhanced emission in the range 460-520 nm with a M/P ratio of X1, where X1 is at least 0.7, a correlated color temperature of 4000-14000 K, and an average color rendering index of at least 70.

2. The lighting device of claim 1, wherein the visible illumination is produced by a system that comprises one or more LEDs, and at least one energy conversion film.

3. The lighting device of claim 2, wherein the one or more LEDs emit light in the range of 445-475 nm.

4. The lighting device of claim 2, wherein the at least one energy conversion film contains diisobutyl 4,10-dicyanoperylene-3,9-dicarboxylate.

5. A lighting device that provides visible illumination with reduced emission in the range 460-520 nm with a M/P ratio of X2, where X2 is no more than 0.40, a correlated color temperature of 2200-4000 K, and an average color rendering index of at least 70.

6. The lighting device of claim 5, wherein the visible illumination is produced by a system that comprises one or more LEDs, and at least one energy conversion film.

7. The lighting device of claim 6, wherein the one or more LEDs emit in the range of 400-460 nm.

8. The lighting device of claim 6, wherein the at least one energy conversion film contains 3-cyanoperylene-9,10-dicarboxylic acid 2′,6′-diiosopropylanilide.

9. A lighting device that can provide visible illumination in either of a first state with a M/P ratio of X1, where X1 is at least 0.70, a correlated color temperature of 4000-14000 K, and an average CRI of at least 70, and of a second state with a M/P ratio of X2, where X2 is no more than 0.40, a correlated color temperature of 2200-4000 K, and an average CRI of at least 70.

10. The lighting device of claim 9, wherein the visible illumination is produced by a system that comprises one or more LEDs, a light guide, and at least one energy conversion component.

11. The lighting system of claim 10, wherein the system comprises one or more illumination sources emitting in the range 445-475 nm which are directed to at least a portion of a first edge of the light guide, and one or more illumination sources emitting in the range 400-450 nm which are directed to at least a portion of a second edge of the light guide.

12. The lighting system of claim 10, wherein the system comprises one or more illumination sources emitting in the range 400-460 nm which are directed to a first edge of the light guide, and to a second edge of the light guide.

13. The lighting system of any of claims 11-12, wherein the illumination sources include LEDs, fluorescent lights, incandescent lights, or any combination thereof.

14. An apparatus for converting a existing light source into a biofriendly light source, the apparatus comprising
an energy conversion component removably attached to the existing light source, wherein the energy conversion component is configured to convert light from the existing light source into a light in either of a first state with a M/P ratio of X1, where X1 is at least 0.70, a correlated color temperature of 4000-14000 K, and an average CRI of at least 70, and of a second state with a M/P ratio of X2, where X2 is no more than 0.40, a correlated color temperature of 2200-4000 K, and an average CRI of at least 70.

15. The apparatus of claim 14, wherein the existing light source is a fluorescent light source, an incandescent light source, an LED, a gas discharge light source, or any combination thereof.

16. A lighting device comprising:
a frame;
a light source disposed along an interior of an edge of the frame;
a light guide panel disposed in the frame, an edge of the light guide panel being in communication with the light source disposed on the interior of the corresponding edge of the frame, the light guide panel being configured to direct light received from the light source through a first surface of the light guide panel to a viewing hemisphere; and
an energy conversion component disposed on the first surface of the light guide panel, the energy conversion component being configured to convert the light received from the light source to light having a M/P ratio of X1, where X1 is at least 0.7.

17. The lighting device of claim 16, wherein the light source comprises one or more LEDs.

18. The lighting device of claim 17, wherein the one or more LEDs emit light in the range of 445-475 nm.

19. The lighting device of claim 16, wherein the energy conversion component comprises a film containing diisobutyl 4,10-dicyanoperylene-3,9-dicarboxylate.

20. The lighting device of claim 16, wherein the light converted by the energy conversion component has a CRI Rₐ of at least 70 and a CCT of 4000-14000 K.

21. The lighting device of claim 16, wherein the energy conversion component includes at least one energy conversion element producing light in the range 475-780 nm.

22. A lighting device comprising:
a frame;
a light source disposed along an interior of an edge of the frame;
a light guide panel disposed in the frame, an edge of the light guide panel being in communication with the light source disposed on the interior of the corresponding edge of the frame, the light guide panel being configured to direct light received from the light source through a first surface of the light guide panel to a viewing hemisphere; and
an energy conversion component disposed on the first surface of the light guide panel, the energy conversion component being configured to convert the light received from the light source to light having a M/P ratio of X2, where X2 is no more than 0.4.

23. The lighting device of claim 22, wherein the light source comprises one or more LEDs.

24. The lighting device of claim 23, wherein the one or more LEDs emit light in the range of 400-460 nm.

25. The lighting device of claim 22, wherein the energy conversion component comprises a film containing 3-cyanoperylene-9,10-dicarboxylic acid 2′,6′-diiosopropylanilide.

26. The lighting device of claim 22, wherein the light converted by the energy conversion component has a CRI Rₐ of at least 70 and a CCT of 2200-4000 K.

27. The lighting device of claim 22, wherein the energy conversion component includes at least one energy conversion element producing light in the range 500-730 nm.

28. A lighting device comprising:
a frame;
a light source disposed along an interior of an edge of the frame;
a light guide panel disposed in the frame, an edge of the light guide panel being in communication with the light source disposed on the interior of the corresponding edge of the frame, the light guide panel being configured to direct light received from the light source through a first surface of the light guide panel to a viewing hemisphere; and
an energy conversion component disposed between the light source and the corresponding edge of the light guide panel, the energy conversion component being configured to convert the light received from the light source to light having a different spectrum than that received from the light source.

29. The lighting device of claim 28, wherein the converted light has a M/P ratio of X2, where X2 is no more than 0.4.

30. The lighting device of claim 28, wherein the converted light has a M/P ratio of X1, where X1 is at least 0.7.

31. A lighting device comprising:
a frame;
a first light source disposed along an interior of a first edge of the frame and a second light source disposed along an interior of a second edge of the frame;
a light guide panel disposed in the frame, edges of the light guide panel being in communication with the first and second light sources disposed on the interior of the corresponding edge of the frame, the light guide panel being configured to direct light received from the first and second light sources through a first surface of the light guide panel to a viewing hemisphere;
a first energy conversion component disposed between the first light source and the corresponding edge of the light guide panel, the first energy conversion component being configured to convert the light received from the first light source to light having a M/P ratio of X1, where X1 is at least 0.7; and
a second energy conversion component disposed between the second light source and the corresponding edge of the light guide panel, the second energy conversion component being configured to convert the light received from the second light source to light having a M/P ratio of X2, where X2 is no more than 0.4.

32. The lighting device of claim 31, wherein the first energy conversion component comprises a film containing diisobutyl 4,10-dicyanoperylene-3,9-dicarboxylate.

33. The lighting device of claim 31, wherein the second energy conversion component comprises a film containing 3-cyanoperylene-9,10-dicarboxylic acid 2′,6′-diiosopropylanilide.

34. The lighting device of claim 31, wherein the first light source and the second light source have independent electrical control systems.

35. The lighting device of claim 31, wherein the first and the second light sources are controlled independently to enable a transition between the first light source and the second light source to illuminate the corresponding energy conversion components based on a user preference, time of the day, weather conditions, or local sunrise/sunset times.

36. A lighting device comprising:
a light source having a front face through which light is emitted;
an energy conversion component comprising a plurality of portions, the energy conversion component being positioned to expose one of the plurality of portions to the front face, wherein each of the plurality of portions of the energy conversion component converts light received from the light source into the light having a different spectrum; and
a controller configured to control the energy conversion component to cause a portion among the plurality of portions of the energy conversion component to be exposed to the front face.

37. A lighting device comprising:
a frame;
an opaque reflector positioned within the frame;
a light source disposed on the opaque reflector;
an energy conversion component disposed on the light source such that the light source is disposed between the opaque reflector and the energy conversion component, the energy conversion component being configured to convert the light received from the light source to light having a M/P ratio of X1, where X1 is at least 0.7; and
a diffuser disposed above the energy conversion component and configured to disperse the converted light into a viewing hemisphere through an exit surface opposite the opaque reflector.

38. The lighting device of claim 37, wherein the light source comprises one or more LEDs.

39. The lighting device of claim 38, wherein the one or more LEDs emit light in the range of 445-475 nm.

40. The lighting device of claim 37, wherein the energy conversion component comprises a film containing diisobutyl 4,10-dicyanoperylene-3,9-dicarboxylate.

41. The lighting device of claim 36, wherein the light converted by the energy conversion component has a CRI Rₐ of at least 70 and a CCT of 4000-14000 K.

42. The lighting device of claim 36, wherein the energy conversion component includes at least one energy conversion element producing light in the range 475-780 nm.

43. A lighting device comprising:
a frame;
an opaque reflector positioned within the frame;
a light source disposed on the opaque reflector;
an energy conversion component disposed on the light source such that the light source is disposed between the opaque reflector and the energy conversion component, the energy conversion component being configured to convert the light received from the light source to light having a M/P ratio of X2, where X2 is no more than 0.4; and
a diffuser disposed above the energy conversion component and configured to disperse the converted light into a viewing hemisphere through an exit surface opposite the opaque reflector.

44. The lighting device of claim 43, wherein the light source comprises one or more LEDs.

45. The lighting device of claim 44, wherein the one or more LEDs emit light in the range of 400-460 nm.

46. The lighting device of claim 43, wherein the energy conversion component comprises a film containing 3-cyanoperylene-9,10-dicarboxylic acid 2′,6′-diiosopropylanilide.

47. The lighting device of claim 43, wherein the light converted by the energy conversion component has a CRI Rₐ of at least 70 and a CCT of 2200-4000 K.

48. The lighting device of claim 43, wherein the energy conversion component includes at least one energy conversion element producing light in the range 500-730 nm.

49. A lighting device comprising:
a frame;
an opaque reflector positioned within the frame;
a first light source and a second light source disposed on the opaque reflector;
a first energy conversion component disposed on the first light source and a second energy conversion component disposed on the second light source such that the first and the second light sources are disposed between the opaque reflector and the corresponding energy conversion components, the first and the second energy conversion components being configured to convert the light received from the corresponding light source to a light having a different spectrum than that received from the light source; and
a diffuser disposed above the first and the second energy conversion components and configured to disperse the converted light into a viewing hemisphere through an exit surface opposite the opaque reflector.

50. The lighting device of claim 49, wherein the converted light has a M/P ratio of X2, where X2 is no more than 0.4.

51. The lighting device of claim 49, wherein the converted light has a M/P ratio of X1, where X1 is at least 0.7.

52. A lighting device comprising:
a frame;
an opaque reflector positioned within the frame;
a plurality of light source disposed on the opaque reflector, the plurality of light sources emitting light with the same characteristics;
a first energy conversion component disposed on a first set of light sources among the plurality of light sources and a second energy conversion component disposed on a second set of light sources among the plurality of light sources such that the first and the second set of light sources are disposed between the opaque reflector and the corresponding energy conversion components, the first energy conversion component being configured to convert the light received from the first set of light sources to light having a M/P ratio of X1, where X1 is at least 0.7, and the second energy conversion component being configured to convert the light received from the second set of light sources to light having a M/P ratio of X2, where X2 is no more than 0.4; and a diffuser disposed above the energy conversion components and configured to disperse the converted light into a viewing hemisphere through an exit surface opposite the opaque reflector.

53. The lighting device of claim 52, wherein the first energy conversion component comprises a film containing diisobutyl 4,10-dicyanoperylene-3,9-dicarboxylate.

54. The lighting device of claim 52, wherein the second energy conversion component comprises a film containing 3-cyanoperylene-9,10-dicarboxylic acid 2′,6′-diiosopropylanilide.

55. A system for providing biofriendly lighting, comprising:
a light source comprising a white light source and a housing; and
an energy conversion film removably disposed over an exit surface of the light source such that light emitted by the light source passes through the energy conversion film before exiting to the viewing hemisphere to reach a user,
wherein the energy conversion component is configured to convert the light received from the light source to light having a different spectrum than that received from the light source.

56. The system of claim 55, wherein the energy conversion component is configured to convert the light received from the light source to light having a M/P ratio of X1, where X1 is at least 0.7, a correlated color temperature of 4000-14000 K, and an average color rendering index of at least 70.

57. The system of claim 56, wherein the at least one energy conversion film contains diisobutyl 4,10-dicyanoperylene-3,9-dicarboxylate.

58. The system of claim 55, wherein the energy conversion component is configured to convert the light received from the light source to light having a M/P ratio of X2, where X2 is no more than 0.4, a CRI Rₐ of at least 70 and a CCT of 2200-4000 K.

59. The system of claim 58, wherein the at least one energy conversion film contains 3-cyanoperylene-9,10-dicarboxylic acid 2′,6′-diiosopropylanilide.

60. The system of claim 55, wherein the white light source include LEDs, fluorescent lights, incandescent lights, or any combination thereof.

61. An apparatus for converting a existing light source into a biofriendly light source, the apparatus comprising:
an energy conversion component removably attached to the existing light source,
wherein the energy conversion component is configured to convert light from the existing light source into a light in either of a first state with a M/P ratio of X1, where X1 is at least 0.70, a correlated color temperature of 4000-14000 K, and an average CRI of at least 70, and of a second state with a M/P ratio of X2, where X2 is no more than 0.40, a correlated color temperature of 2200-4000 K, and an average CRI of at least 70.

62. A method for converting an existing white light source into a biofriendly lighting device, the method comprising:
removably attaching an energy conversion film to a front face of the existing white light source, wherein the energy conversion film is configured to convert the light received from the light source to light having a M/P ratio of X2, where X2 is no more than 0.4, a CRI Rₐ of at least 70 and a CCT of 2200-4000 K.

63. A method for converting an existing white light source into a biofriendly lighting device, the method comprising:
pivotably attaching strips of an energy conversion film to a front face of the existing white light source, the strips being configured to pivot from a first position to a second position,
wherein light emitted by the white light source does not pass through the strips of the energy conversion film when the strips are in the first position and the light emitted by the white light source not passes through the strips of the energy conversion film when the strips are in the second position,
wherein the energy conversion film is configured to convert the light received from the light source to light having a M/P ratio of X2, where X2 is no more than 0.4, a CRI Rₐ of at least 70 and a CCT of 2200-4000 K.

64. The method of claim 63, wherein the strips of the energy conversion film are configured to be pivoted from the first position to the second position manually.

65. The method of claim 63, wherein the strips of the energy conversion film are configured to be pivoted from the first position to the second position by a motorized assembly.

66. A lighting device comprising:
a light source having a front face through which light is emitted;
an energy conversion component comprising a plurality of portions, the energy conversion component being positioned to expose one of the plurality of portions to the front face, wherein each of the plurality of portions of the energy conversion component converts light received from the light source into the light having a different spectrum; and
a controller configured to control the energy conversion component to cause a portion among the plurality of portions of the energy conversion component to be exposed to the front face.
